(19) United States
(12) Patent Application Publication
(10) Pub. No.: US 2026/0271299 A1
(43) Pub. Date: Sep. 10, 2026

(54) STEEP-SWITCHING MEMORY DEVICE AND THEIR MANUFACTURING METHODS, RESERVOIR COMPUTING SYSTEMS APPLYING THE SAME, AUTONOMOUS VEHICLE SYSTEMS APPLYING THE SAME, SEMICONDUCTOR INSPECTION SYSTEMS APPLYING THE SAME, AND ELECTROCARDIOGRAM ANALYSIS SYSTEMS APPLYING THE SAME

(71) Applicant: RESEARCH & BUSINESS FOUNDATION SUNGKYUNKWAN UNIVERSITY, Suwon-si (KR)

(72) Inventors: Sung Joo LEE, Seongnam-si (KR); Seong Kweon KANG, Suwon-si (KR); Yoon Myung Lee, Seongnam-si (KR); Sang Min LEE, Suwon-si (KR); Jae Rok KIM, Suwon-si (KR); Sung Pyo BAEK, Suwon-si (KR); Tae Ho KANG, Seoul (KR); Cheol Hwa JANG, Suwon-si (KR); Jong Min NOH, Suwon-si (KR); Na Yeong LEE, Suwon-si (KR); Chang Yong PARK, Suwon-si (KR); Gi Hyeon BHIN, Suwon-si (KR); Chang Young KIM, Anyang-si (KR)

(21) Appl. No.: 19/556,069

(22) Filed: Mar. 4, 2026

(30) Foreign Application Priority Data
Mar. 6, 2025 (KR) 10-2025-0029062
Mar. 6, 2025 (KR) 10-2025-0029065
Mar. 6, 2025 (KR) 10-2025-0029066
Jun. 4, 2025 (KR) 10-2025-0073158

(51) Int. Cl. H10B 51/30

(52) U.S. Cl. CPC H10B 51/30

(57) ABSTRACT

Provided is a steep-switching memory device. The steep-switching memory device includes: a source electrode and a drain electrode disposed on a substrate to be spaced apart from each other; a ferroelectric channel layer disposed on the substrate to cover the source electrode and the drain electrode; an insulating layer disposed on the ferroelectric channel layer; a ferroelectric layer disposed on the insulating layer and having insulating characteristics; and a gate electrode disposed on the ferroelectric layer, in which capacitances of the insulating layer and the ferroelectric layer are controlled, so that an internal voltage, which is formed at a boundary surface between the ferroelectric layer and the insulating layer, is amplified to be higher than a voltage applied to the gate electrode, and steep-switching characteristics having a subthreshold swing (SS) value of less than 60 mV/dec are represented.

### BACKGROUND OF THE INVENTION

### 1. Field of the Invention

The present invention relates to a steep-switching memory device and a method for manufacturing the same, and more specifically, to a steep-switching memory device having a structure in which mutually different ferroelectric materials are bonded to each other, and a method for manufacturing the same.

The steep-switching memory device and the method for manufacturing the same according to an embodiment of the present invention may be applied to a reservoir computing system, an autonomous vehicle system, a semiconductor inspection system, and an electrocardiogram analysis system.

### 2. Description of the Related Art

Research on existing reservoir computing systems has focused on efficiently classifying and predicting time series data by replacing physical devices with reservoir layers, and mainly utilized only the storage capacity of memory devices. Such memory operation characteristics are achieved by utilizing short-term memory characteristics of devices such as CMOS technology, memristor, spintronics, photonics, and ferroelectricity. Through the mechanism, it is possible to extract reservoir outputs including various information such as a time interval, signal strength, and the number of input signals (non-linear transform characteristics), and it is proved that time series information may be efficiently learned only by weight conversion in a reading layer.

However, such studies are fundamentally preprocessed and used under ideal input conditions, and have a limitation in that the effect may not be experimentally verified in an environment with noise. Such limitations greatly hinder the practical applicability and performance of the physical reservoir computing system.

Meanwhile, ferroelectrics have attracted considerable attention due to spontaneous electric dipole polarization and movement of domain walls under external electric field, mechanical deformation, or light irradiation. Oxide ferroelectrics based on an ABO3 structure are generally studied because of spontaneous polarization caused by distortion of off-center B ions. In addition to the oxide ferroelectrics, van der Waals (vdW) layered ferroelectrics (CIPS, α-In₂Se₃, SnS, InSe, and 1T-WTe₂) are leading to paradigm shifts in basic research and technical fields due to their small size (thin layer in atomic units), individual dipoles capable of overcoming the depolarization field, and strong ferroic coupling between dipoles.

Among the 2D ferroelectrics, α-In₂Se₃ has a characteristic in which in-plane (IP) polarization and out-of-plane (OOP) polarization coexist due to a five-layer structure in which intermediate layer Se atoms may be easily displaced left and right inside crystals. Therefore, various studies on α-In₂Se₃ are being conducted.

For example, “Dutta, D.; Mukherjee, S.; Uzhansky, M.; Koren, E. Cross-field optoelectronic modulation via inter-coupled ferroelectricity in 2D In₂Se₃. npj 2D Materials and Applications 2021” has experimentally demonstrated that the dipoles sink in both directions inside α-In₂Se₃, which is controlled by a vertical gate voltage.

For another example, “Rubio-Marcos, F.; Ochoa, D. A.; Del Campo, A.; Garcia, M. A.; Castro, G. R.; Fernandez, J. F.; Garcia, J. E. Reversible optical control of macroscopic polarization in ferroelectrics. Nature Photonics 2017” has proposed the possibility of switching a polarization region in a non-contact and remote manner by discovering a polarity order change due to light in the ferroelectric.

As still another example, “Xue, F.; He, X.; Liu, W.; Periyanagounder, D.; Zhang, C.; Chen, M.; Lin, C. H.; Luo, L.; Yengel, E.; Tung, V.; et al. Optoelectronic Ferroelectric Domain-Wall Memories Made from a Single Van Der Waals Ferroelectric. advanced Functional Materials 2020” has demonstrated a memory effect due to movement of ferroelectric region walls controlled by external optical illumination of the α-In₂Se₃ device.

### RELATED ART DOCUMENT

### Non-Patent Documents

Dutta, D.; Mukherjee, S.; Uzhansky, M.; Koren, E. Cross-field optoelectronic modulation via inter-coupled ferroelectricity in 2D In₂Se₃. npj 2D Materials and Applications 2021
Rubio-Marcos, F.; Ochoa, D. A.; Del Campo, A.; Garcia, M. A.; Castro, G. R.; Fernoandez, J. F.; Garcia, J. E. Reversible optical control of macroscopic polarization in ferroelectrics. Nature Photonics 2017
Xue, F.; He, X.; Liu, W.; Periyanagounder, D.; Zhang, C.; Chen, M.; Lin, C. H.; Luo, L.; Yengel, E.; Tung, V.; et al. Optoelectronic Ferroelectric Domain-Wall Memories Made from a Single Van Der Waals Ferroelectric. Advanced Functional Materials 2020

### SUMMARY OF THE INVENTION

One technical problem to be solved by the present invention is to provide a steep-switching memory device and a method for manufacturing the same.

Another technical problem to be solved by the present invention is to provide a steep-switching memory device using mutually different ferroelectric material layers and a method for manufacturing the same.

Still another technical problem to be solved by the present invention is to provide a steep-switching memory device capable of amplifying a voltage applied to a gate electrode therein and a method for manufacturing the same.

Still another technical problem to be solved by the present invention is to provide a steep-switching memory device having a subthreshold swing value of less than 60 mV/dec and a method for manufacturing the same.

Still another technical problem to be solved by the present invention is to provide a steep-switching memory device representing hysteresis characteristics having a wide memory window and a method for manufacturing the same.

Still another technical problem to be solved by the present invention is to provide a reservoir computing system to which a steep-switching memory device is applied.

Still another technical problem to be solved by the present invention is to provide a reservoir computing system implementing noise filtering characteristics using steep-switching characteristics of a steep-switching memory device.

Still another technical problem to be solved by the present invention is to provide a reservoir computing system capable of filtering noise without additional noise filtering circuits and devices.

Still another technical problem to be solved by the present invention is to provide a reservoir computing system implementing short-term memory characteristics using hysteresis characteristics of a steep-switching memory device.

Still another technical problem to be solved by the present invention is to provide a reservoir computing system implementing non-linear transform characteristics using steep-switching characteristics and hysteresis characteristics of a steep-switching memory device.

Still another technical problem to be solved by the present invention is to provide an autonomous vehicle system to which a steep-switching memory device is applied.

Still another technical problem to be solved by the present invention is to provide a semiconductor inspection system to which a steep-switching memory device is applied.

Still another technical problem to be solved by the present invention is to provide an electrocardiogram analysis system to which a steep-switching memory device is applied.

The technical problems to be solved by the present invention are not limited to those described above.

To solve the above technical problems, the present invention provides a steep-switching memory device.

According to one embodiment, the steep-switching memory device may include: a source electrode and a drain electrode disposed on a substrate to be spaced apart from each other; a ferroelectric channel layer disposed on the substrate to cover the source electrode and the drain electrode; an insulating layer disposed on the ferroelectric channel layer; a ferroelectric layer disposed on the insulating layer and having insulating characteristics; and a gate electrode disposed on the ferroelectric layer, in which capacitances of the insulating layer and the ferroelectric layer may be controlled, so that an internal voltage, which is formed at a boundary surface between the ferroelectric layer and the insulating layer, may be amplified to be higher than a voltage applied to the gate electrode, and steep-switching characteristics having a subthreshold swing (SS) value of less than 60 mV/dec may be represented.

According to one embodiment, the capacitances of the insulating layer and the ferroelectric layer may be controlled to satisfy the following <Expression 1>, <Expression 2>, and <Expression 3>.

$${C}_{FE} < 0 \qquad < Expression 1 >$$

$$( {C}_{F E} : Capacitance of the ferroelectric layer )$$

$$\vert {C}_{FE} \vert > {C}_{DE} \qquad < Expression 2 >$$

$$( \vert {C}_{FE} \vert : Absolute value of capacitance of the ferroelectric layer , {C}_{DE} : Capacitace of the insulating layer )$$

$${C}_{ST} > 0 \qquad < Expression 3 >$$

$$( {C}_{ST} : Total capacitance of a stack structure in which the ferroelectric layer is stacked on the insulating layer )$$

According to one embodiment, the insulating layer and the ferroelectric layer may be electrically connected in series.

According to one embodiment, when a voltage equal to or higher than a reference voltage is applied to the gate electrode, dipole coupling may be formed between the ferroelectric layer and the ferroelectric channel layer such that a polarization direction of the ferroelectric layer is the same as a polarization direction of the ferroelectric channel layer.

According to one embodiment, hysteresis characteristics having a memory window of 4.3 V may be represented due to the dipole coupling between the ferroelectric layer and the ferroelectric channel layer.

According to one embodiment, the steep-switching memory device may have a subthreshold swing value of less than 20 mV/dec.

According to one embodiment, the ferroelectric channel layer may include any one of alpha-indium selenide (α-In₂Se₃), MoSSe, MoTe, SnS, SnSe, SnTe, GeS, GeSe, and GeTe.

According to one embodiment, the insulating layer may include aluminum oxide (Al₂O₃), silicon oxide (SiO₂), hafnium oxide (HfO₂), and hexagonal boron nitride (h-BN).

According to one embodiment, the ferroelectric layer may include any one of hafnium zirconium oxide (HZO), CuCrP₂S₆, CuCrP₂Se₆, CuVP₂S₆, CuVP₂Se₆, CuInP₂Se₆, CuInP₂S₆(CIPS), AgBiP₂Se₆, Sc₂CO₂, GaTeCl, and g-C₆N₈H.

According to one embodiment, the capacitances of the insulating layer and the ferroelectric layer may be controlled as thicknesses of the insulating layer and the ferroelectric layer are controlled.

According to another embodiment, the steep-switching memory device may include: a source electrode and a drain electrode disposed on a substrate to be spaced apart from each other; a ferroelectric channel layer disposed on the substrate to cover the source electrode and the drain electrode; an insulating layer disposed on the ferroelectric channel layer; a ferroelectric layer disposed on the insulating layer and having insulating characteristics; and a gate electrode disposed on the ferroelectric layer, in which the steep-switching memory device may represent hysteresis characteristics having a memory window of 4.3 V, and have a subthreshold swing value of less than 20 mV/dec.

According to another embodiment, as capacitances of the insulating layer and the ferroelectric layer may be controlled to satisfy the following <Expression 1>, <Expression 2>, and <Expression 3>, an internal voltage, which is formed at a boundary surface between the ferroelectric layer and the insulating layer, may be amplified to be higher than a voltage applied to the gate electrode, and steep-switching characteristics having the subthreshold swing value of less than 20 mV/dec may be represented.

$${C}_{FE} < 0 \qquad < Expression 1 >$$

$$( {C}_{F E} : Capacitance of the ferroelectric layer )$$

$$\vert {C}_{FE} \vert > {C}_{DE} \qquad < Expression 2 >$$

$$( \vert {C}_{FE} \vert : Absolute value of capacitance of the ferroelectric layer , {C}_{DE} : Capacitace of the insulating layer )$$

$${C}_{ST} > 0 \qquad < Expression 3 >$$

$$( {C}_{ST} : Total capacitance of a stack structure in which the ferroelectric layer is stacked on the insulating layer ) .$$

According to another embodiment, when a voltage equal to or higher than a reference voltage is applied to the gate electrode, dipole coupling may be formed between the ferroelectric layer and the ferroelectric channel layer such that a polarization direction of the ferroelectric layer is the same as a polarization direction of the ferroelectric channel layer, thereby representing the hysteresis characteristics having the memory window of 4.3 V.

To solve the above technical problems, the present invention provides a method for manufacturing a steep-switching memory device.

According to one embodiment, the method for manufacturing a steep-switching memory device may include: preparing a substrate; forming a source electrode and a drain electrode on the substrate to be spaced apart from each other; forming a ferroelectric channel layer on the substrate to cover the source electrode and the drain electrode; forming an insulating layer on the ferroelectric channel layer; forming a ferroelectric layer having insulating characteristics on the insulating layer; and forming a gate electrode on the ferroelectric layer, in which, in the forming of the insulating layer and the forming of the ferroelectric layer, capacitances of the insulating layer and the ferroelectric layer may be controlled, so that an internal voltage, which is formed at a boundary surface between the ferroelectric layer and the insulating layer, may be amplified to be higher than a voltage applied to the gate electrode, and steep-switching characteristics having a subthreshold swing (SS) value of less than 60 mV/dec may be represented.

According to one embodiment, the capacitances of the insulating layer and the ferroelectric layer may be controlled to satisfy the following <Expression 1>, <Expression 2>, and <Expression 3>.

$${C}_{FE} < 0 \qquad < Expression 1 >$$

$$( {C}_{F E} : Capacitance of the ferroelectric layer )$$

$$\vert {C}_{FE} \vert > {C}_{DE} \qquad < Expression 2 >$$

$$( \vert {C}_{FE} \vert : Absolute value of capacitance of the ferroelectric layer , {C}_{DE} : Capacitace of the insulating layer )$$

$${C}_{ST} > 0 \qquad < Expression 3 >$$

$$( {C}_{ST} : Total capacitance of a stack structure in which the ferroelectric layer is stacked on the insulating layer ) .$$

To solve the above technical problems, the present invention provides an autonomous vehicle system.

According to one embodiment, the autonomous vehicle system may include the steep-switching memory device according to the embodiment, in which an avoidance signal may be output with respect to a target object to perform an avoidance function, and no reaction may occur with respect to objects other than the target object.

To solve the above technical problems, the present invention provides a semiconductor inspection system.

According to one embodiment, the semiconductor inspection system may include the steep-switching memory device according to the embodiment, in which a reaction may occur only with respect to a specific residue within scanning electron microscopy (SEM) and transmission electron microscopy (TEM) analysis results.

To solve the above technical problems, the present invention provides an electrocardiogram analysis system.

According to one embodiment, the electrocardiogram analysis system comprising the steep-switching memory device according to the embodiment, in which an output value may be selectively generated for a specific result among electrocardiogram analysis results.

To solve the above technical problems, the present invention provides a reservoir computing system.

According to one embodiment, the reservoir computing system may include a source electrode and a drain electrode disposed on a substrate to be spaced apart from each other, a ferroelectric channel layer disposed on the substrate to cover the source electrode and the drain electrode, an insulating layer disposed on the ferroelectric channel layer, a ferroelectric layer disposed on the insulating layer and having insulating characteristics, and a gate electrode disposed on the ferroelectric layer, in which noise in an input signal may be filtered using steep-switching characteristics generated by controlling capacitances of the insulating layer and the ferroelectric layer, short-term memory characteristics may be implemented using dipole coupling formed between the ferroelectric channel layer and the ferroelectric layer, non-linear transform characteristics, in which the input signal is non-linearly transformed, may be implemented by the steep-switching characteristics and the short-term memory characteristics, and the steep-switching characteristics may be defined such that an internal voltage formed at a boundary surface between the ferroelectric layer and the insulating layer is amplified to be higher than a voltage applied to the gate electrode, and a subthreshold swing (SS) value is less than 60 mV/dec.

According to one embodiment, a differential value between a maximum value of a voltage, which is applied to the gate electrode so as to have a state where polarization directions of the ferroelectric channel layer and the ferroelectric layer are aligned in opposite directions, and a minimum value of a voltage, which is applied to the gate electrode so as to have a state where the polarization directions of the ferroelectric channel layer and the ferroelectric layer are aligned in the same direction, may be less than 1 V.

According to one embodiment, when the input signal is removed after the input signal is applied such that the dipole coupling is formed between the ferroelectric channel layer and the ferroelectric layer, an output signal value output from the input signal may be gradually reduced for a predetermined time.

According to one embodiment, when the input signal is repeatedly applied, the output signal value may gradually increase as the number of repetitions increases.

According to one embodiment, in the reservoir computing system, the noise in the input signal may be filtered without additional noise filtering circuits and devices.

According to one embodiment, in the reservoir computing system, the input signal may be applied through the gate electrode, and an output signal may be output through the drain electrode.

According to one embodiment, a program operation may be performed as a first voltage higher than a reference voltage is applied, an erase operation may be performed as a second voltage lower than the reference voltage is applied, and a read operation may be performed as a third voltage between the reference voltage and the second voltage is applied.

The steep-switching memory device according to the embodiment of the present invention may include: a source electrode and a drain electrode disposed on a substrate to be spaced apart from each other; a ferroelectric channel layer (for example, α-In₂Se₃) disposed on the substrate to cover the source electrode and the drain electrode; an insulating layer (for example, h-BN) disposed on the ferroelectric channel layer; a ferroelectric layer (for example, CIPS) disposed on the insulating layer and having insulating characteristics; and a gate electrode disposed on the ferroelectric layer, in which, as capacitances of the insulating layer and the ferroelectric layer are controlled, steep-switching characteristics (characteristics in which an internal voltage, which is formed at a boundary surface between the ferroelectric layer and the insulating layer, may be amplified to be higher than a voltage applied to the gate electrode and a subthreshold swing value is less than 60 mV/dec), and hysteresis characteristics having a wide memory window of 4.3 V may be represented.

Accordingly, the steep-switching memory device according to the embodiment may be easily applied to a reservoir computing system requiring noise filtering characteristics, short-term memory characteristics, and non-linear transform characteristics.

### BRIEF DESCRIPTION OF THE DRAWINGS

FIG. 1 is a schematic view for explaining a steep-switching memory device according to an embodiment of the present invention.

FIGS. 2 and 3 are views for explaining steep-switching characteristics and dipole coupling of the steep-switching memory device according to the embodiment of the present invention.

FIG. 4 is a circuit view for explaining voltage amplification of the steep-switching memory device according to the embodiment of the present invention.

FIG. 5 is a view for explaining an energy state distribution of a ferroelectric layer, an insulating layer, and a stack structure according to the embodiment of the present invention.

FIGS. 6 and 7 are views for explaining a hysteresis generation mechanism of the steep-switching memory device according to the embodiment of the present invention.

FIG. 8 is a view for explaining noise filtering characteristics and non-linear transform characteristics of a reservoir computing system according to the embodiment of the present invention.

FIG. 9 is a view for comparing a reservoir computing system having a noise filtering function by itself with a reservoir computing system performing a noise filtering function through an additional pre-processing operation.

FIG. 10 is a flowchart for explaining a method for manufacturing the steep-switching memory device according to the embodiment of the present invention.

FIG. 11 is a schematic view for explaining step S100 in the method for manufacturing the steep-switching memory device according to the embodiment of the present invention.

FIG. 12 is a schematic view for explaining step S200 in the method for manufacturing the steep-switching memory device according to the embodiment of the present invention.

FIG. 13 is a schematic view for explaining step S300 in the method for manufacturing the steep-switching memory device according to the embodiment of the present invention.

FIG. 14 is a schematic view for explaining step S400 in the method for manufacturing the steep-switching memory device according to the embodiment of the present invention.

FIG. 15 is a schematic view for explaining step S500 in the method for manufacturing the steep-switching memory device according to the embodiment of the present invention.

FIG. 16 is a schematic view for explaining step S600 in the method for manufacturing the steep-switching memory device according to the embodiment of the present invention.

FIG. 17 is a view for explaining a steep-switching memory device according to a first modified example of the present invention.

FIG. 18 is a view for explaining a steep-switching memory device according to a second modified example of the present invention.

FIG. 19 is a view for explaining a drain current-gate voltage characteristics of a steep-switching memory device according to an experimental example of the present invention.

FIG. 20 is a view for explaining a change in a subthreshold swing voltage according to a drain current of the steep-switching memory device according to the experimental example of the present invention.

FIG. 21 is a view for explaining drain current-gate voltage characteristics (linear scale) of the steep-switching memory device according to the experimental example of the present invention and an undefined output range between V_{IL} and V_{IH} obtained therefrom.

FIG. 22 is a view for explaining a drain current distribution histogram of the steep-switching memory device according to the experimental example of the present invention.

FIG. 23 is a view for explaining drain current-time (I_{DS}-time) results of short-term memory characteristics according to a pulse voltage applied to a gate electrode of the steep-switching memory device according to the experimental example of the present invention.

FIG. 24 is a view for explaining drain current-time characteristics according to a pulse voltage applied to the gate electrode of the steep-switching memory device according to the experimental example of the present invention.

FIG. 25 is a view for explaining drain current-time characteristics according to a repeated pulse voltage (addition of Gaussian noise) applied to the gate electrode of the steep-switching memory device according to the experimental example of the present invention.

FIG. 26 is a view for explaining Fourier transform results of the repeated pulse voltage (addition of Gaussian noise) applied to the gate electrode of the steep-switching memory device according to the experimental example of the present invention.

FIG. 27 is a view for explaining non-linear transformation output results of the steep-switching memory device according to the experimental example of the present invention, depending on the presence or absence of noise.

FIG. 28 is a schematic view of the entire process of MNIST classification with noise applied.

FIG. 29 is a view for explaining results of change in MNIST data according to an increase of Gaussian noise intensity.

FIG. 30 is a view for explaining a relationship between learning accuracy and the number of repetitions of the reservoir computing system based on an event performed using noise-free MNIST data.

FIG. 31 is a view for explaining recognition rate evaluation results of the reservoir computing system based on an event performed using MNIST data for each noise intensity.

FIG. 32 is a view for explaining confusion matrix results of MNIST classification evaluated under a 15 dB condition.

FIG. 33 is a view for explaining confusion matrix results of evaluation performed under w/o reservoir (virtual data) and w/o noise conditions.

FIG. 34 is a view for explaining confusion matrix results of evaluation performed under w/o reservoir (virtual data) and 20 dB noise conditions.

FIG. 35 is a view for explaining confusion matrix results of evaluation performed under w/o reservoir (virtual data) and 15 dB noise conditions.

FIG. 36 is a view for explaining confusion matrix results of evaluation performed under w/reservoir (data output from the device) and w/o noise conditions.

FIG. 37 is a view for explaining confusion matrix results of evaluation performed under w/reservoir (data output from the device) and w/o noise conditions.

### DETAILED DESCRIPTION OF THE INVENTION

Hereinafter, preferred embodiments of the present invention will be described in detail with reference to the accompanying drawings. However, the present invention may be embodied in different forms and should not be construed as limited to the embodiments set forth herein. Rather, the embodiments are provided so that this disclosure will be thorough and complete, and will fully convey the scope of the present invention to those skilled in the art.

In the present specification, it will be understood that when an element is referred to as being “on” another element, it can be formed directly on the other element or intervening elements may be present. In the drawings, the thicknesses of layers and regions are exaggerated for clarity.

In addition, it will be also understood that although the terms first, second, third, etc. may be used herein to describe various elements, these elements should not be limited by these terms. These terms are only used to distinguish one element from another element. Thus, a first element in some embodiments may be termed a second element in other embodiments without departing from the teachings of the present invention. Embodiments explained and illustrated herein include their complementary counterparts. As used herein, the term “and/or” includes any and all combinations of one or more of the associated listed elements.

As used herein, the singular expression also includes the plural meaning as long as it does not differently mean in the context. In addition, the terms “comprise”, “have” etc., of the description are used to indicate that there are features, numbers, steps, elements, or combinations thereof, and they should not exclude the possibilities of combination or addition of one or more features, numbers, operations, elements, or a combination thereof. Furthermore, it will be understood that when an element is referred to as being “connected” or “coupled” to another element, it may be directly connected or coupled to the other element or intervening elements may be present.

In addition, when detailed descriptions of related known functions or constitutions are considered to unnecessarily cloud the gist of the present invention in describing the present invention below, the detailed descriptions will not be included.

In addition, in the following description of the present invention, reference numerals of a ferroelectric channel layer, an insulating layer, and a ferroelectric layer are described as 200, 300, and 400, respectively, but may also be described as FE₂, DE, and FE₁, respectively.

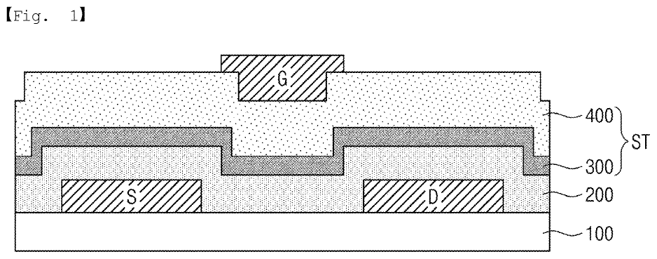

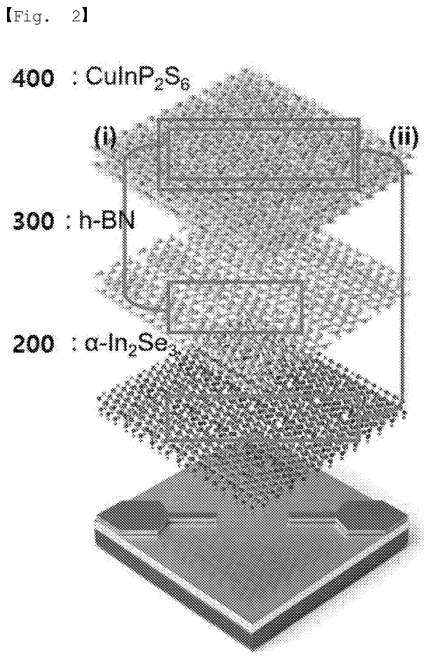

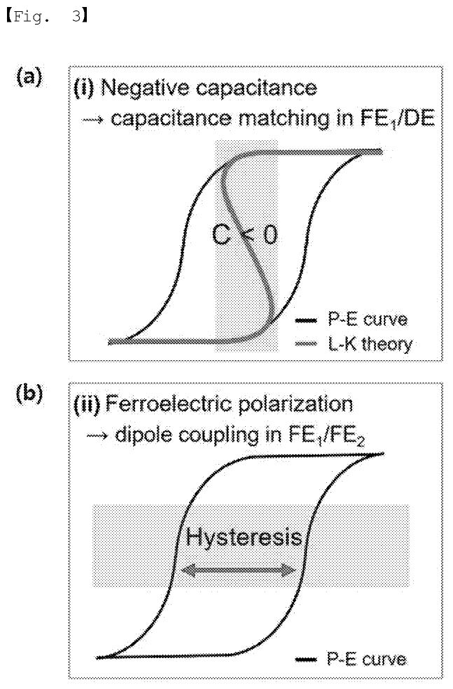

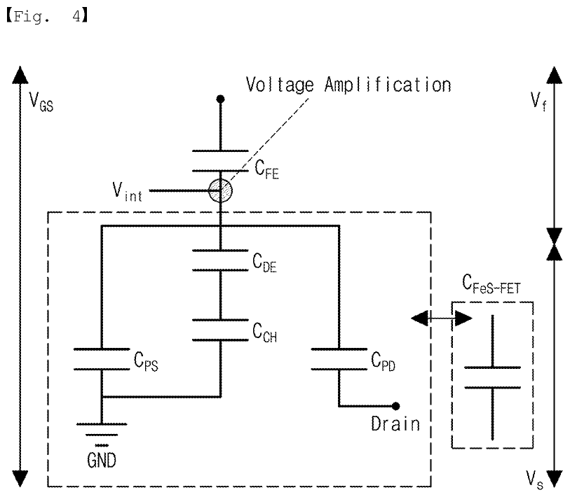

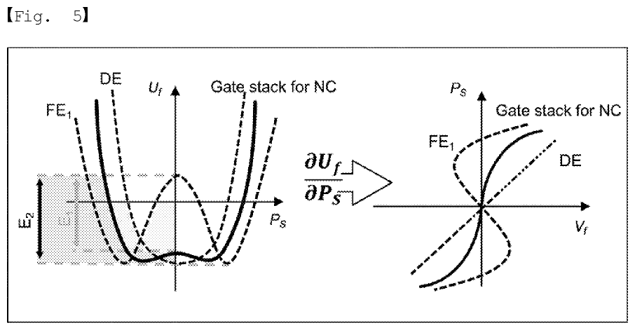

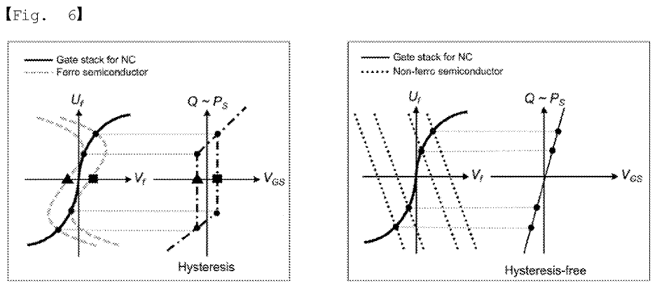

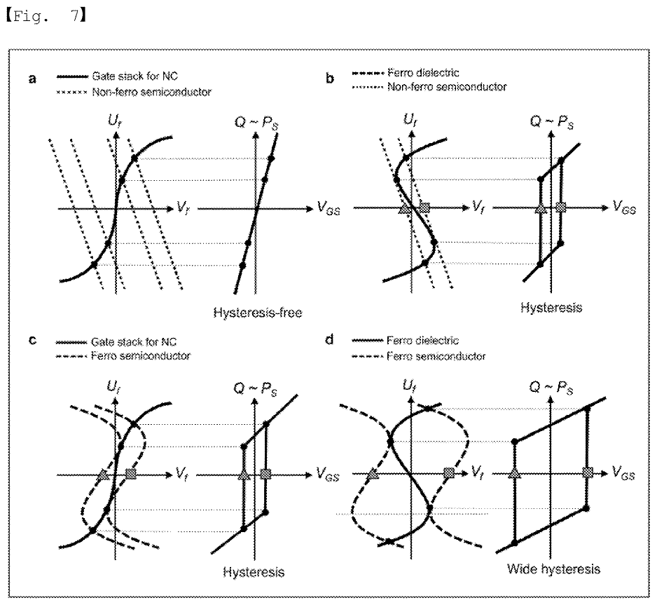

FIG. 1 is a schematic view for explaining a steep-switching memory device according to an embodiment of the present invention, FIGS. 2 and 3 are views for explaining steep-switching characteristics and dipole coupling of the steep-switching memory device according to the embodiment of the present invention, FIG. 4 is a circuit view for explaining voltage amplification of the steep-switching memory device according to the embodiment of the present invention, FIG. 5 is a view for explaining an energy state distribution of a ferroelectric layer, an insulating layer, and a stack structure according to the embodiment of the present invention, and FIGS. 6 and 7 are views for explaining a hysteresis generation mechanism of the steep-switching memory device according to the embodiment of the present invention.

Referring to FIGS. 1 to 4, the steep-switching memory device according to the embodiment of the present invention may include a substrate 100, a source electrode S, a drain electrode D, a ferroelectric channel layer 200, an insulating layer 300, a ferroelectric layer 400, and a gate electrode G. Hereinafter, each component will be described.

The substrate 100 is for supporting the respective components of the steep-switching memory device according to the embodiment, and according to one embodiment, the substrate 100 may be a silicon semiconductor substrate. More specifically, the substrate 100 may be a Si/SiO₂ substrate in which a silicon oxide (SiO₂) layer is formed on a silicon (Si) substrate. Alternatively, according to another embodiment, the substrate 100 may be a compound semiconductor substrate. Alternatively, according to still another embodiment, the substrate 100 may be a glass substrate. Alternatively, according to still another embodiment, the substrate 100 may be a plastic substrate. The type of the substrate 100 is not limited.

The source electrode S and the drain electrode D may be disposed on the substrate 100 to be spaced apart from each other. According to one embodiment, the source electrode S and the drain electrode D may be disposed on the substrate 100 and may be disposed to be spaced apart from each other in a direction parallel to an upper surface of the substrate 100. According to one embodiment, the source electrode S and the drain electrode D may include the same metal. For example, the source electrode S and the drain electrode D may include gold (Au). According to one embodiment, the source electrode S may be grounded with a reference potential (Ground) to provide an operation reference, and the drain electrode D may be used as an output terminal for measuring an output signal.

The ferroelectric channel layer 200 may be disposed on the substrate 100 to cover the source electrode S and the drain electrode D. According to one embodiment, the ferroelectric channel layer 200 may include a material having ferroelectric characteristics and semiconductor characteristics. For example, the ferroelectric channel layer 200 may include alpha-indium selenide (α-In₂Se₃). Alternatively, as another example, the ferroelectric channel layer 200 may include any one of MoSSe, MoTe, SnS, SnSe, SnTe, GeS, GeSe, and GeTe.

Unlike the above description, when the source electrode S and the drain electrode D are disposed on the ferroelectric channel layer 200, a negative capacitance effect may not be easily represented in a stack structure ST to be described later, and dipole coupling between the ferroelectric channel layer 200 and the ferroelectric layer 400 may not be easily formed.

The insulating layer 300 may be disposed on the ferroelectric channel layer 200. For example, the insulating layer 300 may include hexagonal boron nitride (h-BN). Alternatively, as another example, the insulating layer 300 may include any one of aluminum oxide (Al₂O₃), silicon oxide (SiO₂), and hafnium oxide (HfO₂).

The ferroelectric layer 400 may be disposed on the insulating layer 300. According to one embodiment, the ferroelectric channel layer 400 may include a material having insulating characteristics and ferroelectric characteristics. For example, the ferroelectric layer 400 may include CuInP₂S₆ (CIPS). Alternatively, as another example, the ferroelectric layer 400 may include any one of hafnium zirconium oxide (HZO), CuCrP₂S₆, CuCrP₂Se₆, CuVP₂S₆, CuVP₂Se₆, CuInP₂Se₆, AgBiP₂Se₆, Sc₂CO₂, GaTeCl, and g-C₆N₈H.

According to one embodiment, the insulating layer 300 and the ferroelectric layer 400 may be electrically connected in series. In addition, the insulating layer 300 and the ferroelectric layer 400 may be defined as the stack structure ST. That is, a structure in which the ferroelectric layer 400 is stacked on the insulating layer 300 may be defined as the stack structure ST.

The gate electrode G may be disposed on the ferroelectric layer 400. According to one embodiment, the gate electrode G may include metal. In addition, according to one embodiment, the gate electrode G may include the same material as the source electrode S and the drain electrode D. For example, the gate electrode G may also include gold (Au). According to one embodiment, the gate electrode G may be used as an input terminal to which an input signal is applied.

According to one embodiment, as shown in (i) of FIGS. 2 and 3, a negative capacitance effect may be generated in the stack structure ST by matching the capacitances of the insulating layer 300 (DE) and the ferroelectric layer 400 (FE₁), and thus, steep-switching characteristics of the steep-switching memory device may be represented. According to one embodiment, the negative capacitance effect may be defined as a phenomenon of inducing voltage amplification and steep-switching in a stabilized state through capacitance matching with the insulating layer 300 (DE) connected in series, by utilizing an unstable section in which the capacitance is a negative number in a polarization-voltage curve of the ferroelectric layer 400 (FE₁).

More specifically, according to the present invention, hexagonal boron nitride (h-BN) is used as the insulating layer 300, CuInP₂S₆(CIPS) is used as the ferroelectric layer, the insulating layer 300 and the ferroelectric layer 400 are electrically connected in series, and the capacitances of the insulating layer 300 and the ferroelectric layer 400 are controlled to satisfy the following <Expression>1, <Expression 2>, and <Expression 3>, so that the capacitances of the insulating layer 300 and the ferroelectric layer 400 may be matched. According to one embodiment, the capacitances of the insulating layer 300 and the ferroelectric layer 400 may be controlled as thicknesses of the insulating layer 300 and the ferroelectric layer 400 are controlled.

$${C}_{FE} < 0 \qquad < Expression 1 >$$

$$( {C}_{F E} : Capacitance of the ferroelectric layer )$$

$$\vert {C}_{FE} \vert > {C}_{DE} \qquad < Expression 2 >$$

$$( \vert {C}_{FE} \vert : Absolute value of capacitance of the ferroelectric layer , {C}_{DE} : Capacitace of the insulating layer )$$

$${C}_{ST} > 0 \qquad < Expression 3 >$$

$$( {C}_{ST} : Total capacitance of a stack structure in which the ferroelectric layer is stacked on the insulating layer )$$

When the capacitances of the insulating layer 300 (DE) and the ferroelectric layer 400 (FE₁) are matched, as shown in FIGS. 1 and 4, capacitance (CFeS-FET) of a FeS-FET region composed of the insulating layer 300 (DE) and the ferroelectric channel layer 200 (FE₂) may be minimized. Accordingly, most of a voltage V_{GS} applied to the gate electrode G may be concentrated in a region V_{S} between the ferroelectric channel layer 200 (FE₂) and the drain electrode D due to a change in a voltage distribution ratio, and accordingly, the number of free electrons generated in the ferroelectric channel layer 200 (FE₂) may rapidly increase, and thus, steep-switching characteristics having a subthreshold swing (SS) value of 60 mV/dec may be represented.

That is, the steep-switching characteristics may be defined as characteristics in which an internal voltage (an internal node voltage in the stack structure including the insulating layer and the ferroelectric layer), which is formed at a boundary surface between the ferroelectric layer 400 (FE₁) and the insulating layer 300 (DE), is amplified to be higher than a voltage applied to the gate electrode G, and a subthreshold swing value of the device is less than 60 mV/dec.

According to one embodiment, when a voltage equal to or higher than a reference voltage (e.g., 6 V) is applied to the gate electrode G, as shown in (ii) of FIGS. 2 and 3, dipole coupling may be formed between the ferroelectric layer 400 (FE₁) and the ferroelectric channel layer 200 (FE₂) such that a polarization direction of the ferroelectric layer 400 (FE₁) is the same as a polarization direction of the ferroelectric channel layer 200 (FE₂). In addition, according to the present invention, by using α-In₂Se₃ as the ferroelectric channel layer 200 (FE₂) and using CuInP₂S₆ (CIPS) as the ferroelectric layer, it is possible to represent hysteresis characteristics having a wide memory window of 4.3 V due to the dipole coupling between the ferroelectric layer 400 (FE₁) and the ferroelectric channel layer 200 (FE₂).

More specifically, referring to FIG. 5, a ferroelectric (FE₁) of the blue dotted line may have an energy barrier E₂ between two stable states, whereas an insulator (DE) of the green dotted line may have only one stable state. Referring to the red solid line representing the result of the combination (stack structure) of the ferroelectric (FE₁) and the insulator (DE), a system having two stable states may be formed while minimizing the energy barrier. This is referred to as a negative capacitance phenomenon, and a condition for implementing the phenomenon may be referred to as capacitance matching.

When the condition is satisfied, from the viewpoint of device, a voltage distribution in which most of the applied gate voltages are concentrated on a channel is formed due to the lowered energy barrier, and as a result, a voltage amplification effect in a Vint region occurs compared to the existing device, thereby obtaining steep-switching characteristics.

Referring to FIGS. 6 and 7, under the conditions satisfying capacitance matching, coupling between the stack structure (FE₁/DE) and the ferroelectric semiconductor (FE₂) may generate dipole coupling between two ferroelectrics (FE₁/FE₂), thereby enhancing ferroelectric memory characteristics. As shown in the left side of FIG. 6, when the stack structure (FE₁/DE) satisfies the condition for representing the negative capacitance effect, the stack structure (FE₁/DE) has a free energy distribution represented by the red solid line, and as a result of bonding with the ferroelectric semiconductor (FE₂), two intersection points appear under each of the two voltage conditions, that is, the triangle and square conditions, which may induce the occurrence of two stable states, that is, hysteresis. On the other hand, as shown in the right side of FIG. 6, in the case of the combination with a general semiconductor (non-ferro semiconductor), only a single contact point is formed under all voltage conditions, so that hysteresis is not generated. In addition, as can be seen from FIG. 7, it can be seen that the coupling between the stack structure (FE₁/DE) and the ferroelectric semiconductor (FE₂) represents hysteresis characteristics having a wide memory window, compared to a case where the stack structure (FE₁/DE) does not satisfy the capacitance matching so that the negative capacitance effect is not represented and a case where a non-ferroelectric material is used as a semiconductor material. That is, it can be seen that the steep-switching and ferroelectric memory characteristics may be simultaneously secured through the heterojunction of the ferroelectric insulator (FE₁)/insulator (DE)/ferroelectric semiconductor (FE₂).

As a result, the steep-switching memory device according to the embodiment of the present invention may include: a source electrode and a drain electrode disposed on a substrate to be spaced apart from each other; a ferroelectric channel layer (for example, α-In₂Se₃) disposed on the substrate to cover the source electrode and the drain electrode; an insulating layer (for example, h-BN) disposed on the ferroelectric channel layer; a ferroelectric layer (for example, CIPS) disposed on the insulating layer and having insulating characteristics; and a gate electrode disposed on the ferroelectric layer, in which, as capacitances of the insulating layer and the ferroelectric layer are controlled to satisfy <Expression 1>, <Expression 2>, and <Expression 3> described above, steep-switching characteristics (characteristics in which an internal voltage, which is formed at a boundary surface between the ferroelectric layer and the insulating layer, may be amplified to be higher than a voltage applied to the gate electrode and a subthreshold swing value is less than 60 mV/dec), and hysteresis characteristics having a wide memory window of 4.3 V may be represented.

Accordingly, the steep-switching memory device according to the embodiment may be easily applied to a reservoir computing system requiring noise filtering characteristics, short-term memory characteristics, and non-linear transform characteristics. Hereinafter, a reservoir computing system using the steep-switching memory device according to the embodiment will be described.

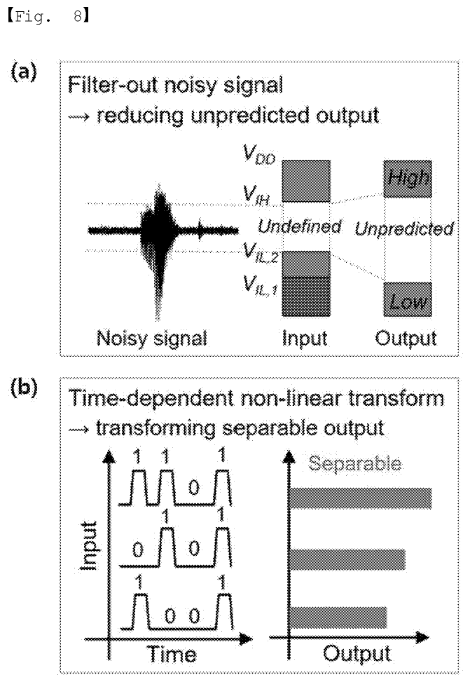

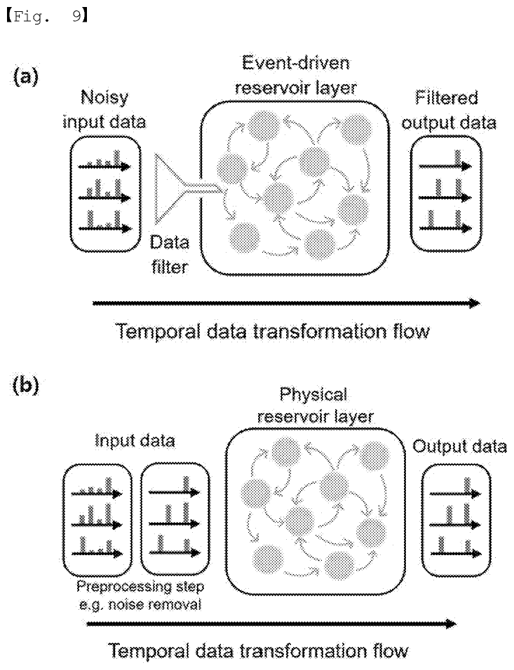

FIG. 8 is a view for explaining noise filtering characteristics and non-linear transform characteristics of a reservoir computing system according to the embodiment of the present invention, and FIG. 9 is a view for comparing a reservoir computing system having a noise filtering function by itself with a reservoir computing system performing a noise filtering function through an additional pre-processing operation.

Referring to FIG. 8(a), the reservoir computing system according to the embodiment may filter noise in an input signal by using steep-switching characteristics (characteristics generated by controlling the capacitances of the insulating layer and the ferroelectric layer) of the steep-switching memory device according to the embodiment. More specifically, since the steep-switching memory device according to the embodiment has a low subthreshold swing value of less than 25 mV/dec (19 mV/dec in a program operation, 23 mV/dec in an erase operation), a differential value between a maximum value V_{IL} (2) of a voltage, which is applied to the gate electrode G so as to have a state where the polarization directions of the ferroelectric channel layer 200 and the ferroelectric layer 400 are aligned in opposite directions (Low state), and a minimum value V_{IH} of a voltage, which is applied to the gate electrode G so as to have a state where the polarization directions of the ferroelectric channel layer 200 and the ferroelectric layer 400 are aligned in the same direction (High state), may be less than 1 V. That is, a generation range of an undefined (unpredicted) output value that is not defined as the Low state and the High state may be minimized, and a current that is less than the voltage V_{IL} applied to the gate electrode G to have the Low state may be filtered close to 0. In other words, noise filtering may be performed by minimizing a low signal output of input data and a generation probability of the undefined output value due to steep-switching characteristics of the steep-switching memory device. Thus, although the conventional reservoir computing system requires additional circuits and devices for filtering noise as shown in FIG. 9(b), the reservoir computing system according to the embodiment may filter noise in the input signal without additional circuits and devices as shown in FIG. 9(a).

Further, referring to FIG. 8(b), the reservoir computing system according to the embodiment may implement short-term memory characteristics using wide hysteresis characteristics (characteristics generated from dipole coupling formed between the ferroelectric channel layer and the ferroelectric layer) of the steep-switching memory device according to the embodiment, and non-linear transform characteristics may be implemented by the steep-switching characteristics and the short-term memory characteristics. According to one embodiment, the non-linear transform characteristics are characteristics in which the input signal is non-linearly transformed, which may mean characteristics in which an output does not linearly react to the input signal and a complex output pattern is generated according to the size, order, or period of the input.

More specifically, when the input signal is removed after the input signal (e.g., a pulse voltage) is applied such that dipole coupling is formed between the ferroelectric channel layer 200 and the ferroelectric layer 400, the output signal value (e.g., a current value) output from the input signal may not be rapidly reduced for a short time, but may be gradually reduced for a predetermined time. That is, even after the input pulse disappears, an output current may be slowly restored without immediately falling to 0. In addition, when the input signal is repeatedly applied (e.g., when the pulse voltage is repeatedly applied with a specific period), the output signal value may gradually increase as the number of repetitions increases. Accordingly, short-term memory characteristics of memorizing a recent input history for a short time may be confirmed.

According to one embodiment, the reservoir computing system according to the embodiment may perform a program operation as a voltage of a first voltage (e.g., 6 V or 7 V) higher than or equal to a reference voltage (e.g., 6 V) is applied. Alternatively, an erase operation may be performed as a voltage of a second voltage (e.g., 1.7 V) less than the reference voltage is applied. Alternatively, a read operation may be performed as a third voltage (e.g., 3 V) between the reference voltage and the second voltage is applied.

As a result, the reservoir computing system may include a source electrode S and a drain electrode D disposed to be spaced apart from each other, a ferroelectric channel layer 200 configured to cover the source electrode S and the drain electrode D, an insulating layer 300 disposed on the ferroelectric channel layer 200, a ferroelectric layer 400 disposed on the insulating layer 300, and a gate electrode G disposed on the ferroelectric layer 400, in which noise in an input signal may be filtered using steep-switching characteristics generated by controlling capacitances of the insulating layer 300 and the ferroelectric layer 400, short-term memory characteristics may be implemented using dipole coupling formed between the ferroelectric channel layer 200 and the ferroelectric layer 400, and non-linear transform characteristics, in which the input signal is non-linearly transformed, may be implemented by the steep-switching characteristics and the short-term memory characteristics.

Hereinabove, the steep-switching memory device and the reservoir computing system according to the embodiment have been described. Hereinafter, a method for manufacturing a steep-switching memory device according to an embodiment of the present invention will be described.

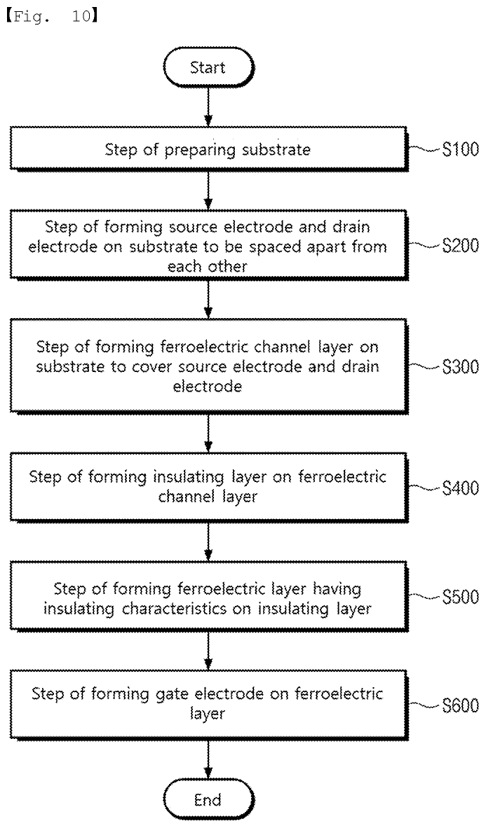

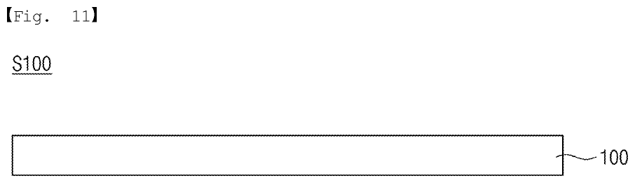

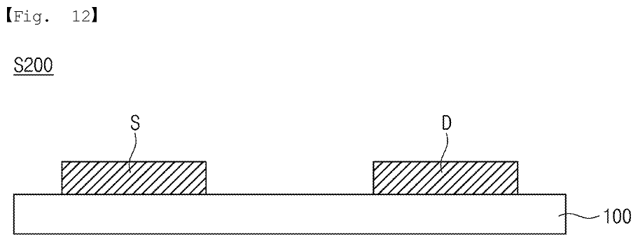

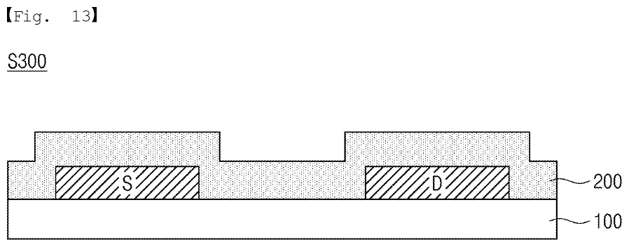

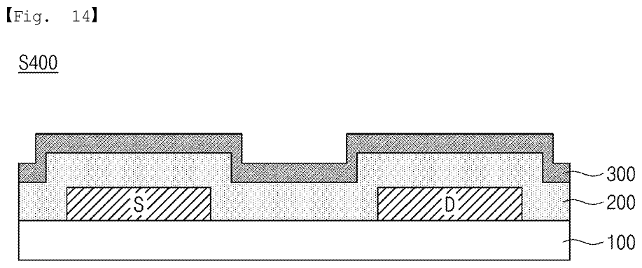

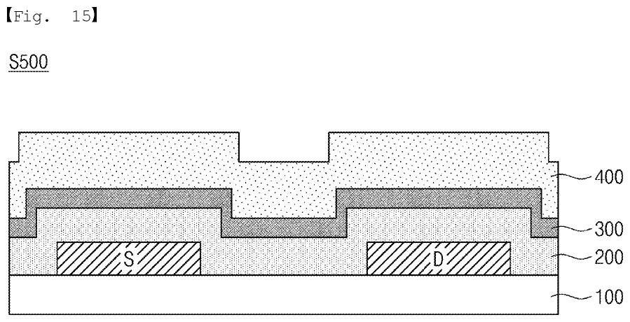

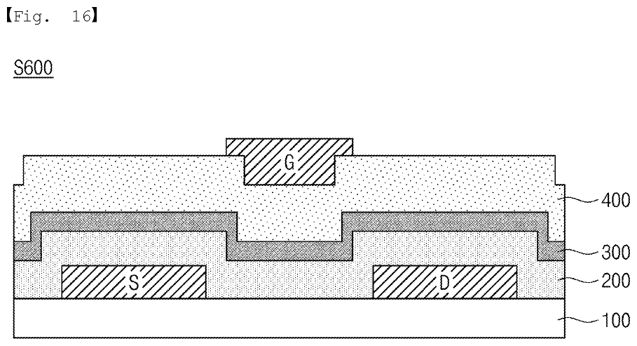

FIG. 10 is a flowchart for explaining a method for manufacturing the steep-switching memory device according to the embodiment of the present invention, FIG. 11 is a schematic view for explaining step S100 in the method for manufacturing the steep-switching memory device according to the embodiment of the present invention, FIG. 12 is a schematic view for explaining step S200 in the method for manufacturing the steep-switching memory device according to the embodiment of the present invention, FIG. 13 is a schematic view for explaining step S300 in the method for manufacturing the steep-switching memory device according to the embodiment of the present invention, FIG. 14 is a schematic view for explaining step S400 in the method for manufacturing the steep-switching memory device according to the embodiment of the present invention, FIG. 15 is a schematic view for explaining step S500 in the method for manufacturing the steep-switching memory device according to the embodiment of the present invention, and FIG. 16 is a schematic view for explaining step S600 in the method for manufacturing the steep-switching memory device according to the embodiment of the present invention.

Referring to FIGS. 10 and 11, a substrate 100 may be prepared (S100). According to one embodiment, the substrate 100 may be a silicon semiconductor substrate. More specifically, the substrate 100 may be a Si/SiO₂ substrate in which a silicon oxide (SiO₂) layer is formed on a silicon (Si) substrate. Alternatively, according to another embodiment, the substrate 100 may be a compound semiconductor substrate. Alternatively, according to still another embodiment, the substrate 100 may be a glass substrate. Alternatively, according to still another embodiment, the substrate 100 may be a plastic substrate. The type of the substrate 100 is not limited.

Referring to FIGS. 10 and 12, a source electrode S and a drain electrode D may be formed on the substrate 100 to be spaced apart from each other (S200). According to one embodiment, the source electrode S and the drain electrode D may be formed by coating polymethyl methacrylate (PMMA) on the substrate 100, etching a partial region thereof through electron beam lithography to expose the substrate 100, and depositing gold (Au) on the exposed substrate 100 by using an electron beam evaporation method.

Referring to FIGS. 10 and 13, a ferroelectric channel layer 200 may be formed on the substrate 100 to cover the source electrode S and the drain electrode D (S300). According to one embodiment, the ferroelectric channel layer 200 may be formed by peeling off an α-In2Se3 layer from an α-In2Se3 bulk using a Scotch tape, and dry transforming the peeled α-In2Se3 layer onto the substrate 100 on which the source electrode S and the drain electrode D are formed.

Referring to FIGS. 10 and 14, an insulating layer 300 may be formed on the ferroelectric channel layer 200 (S400). According to one embodiment, the insulating layer 300 may be formed by peeling off a h-BN layer from a h-BN bulk using a Scotch tape, and dry transforming the peeled h-BN layer on the ferroelectric channel layer 200.

Referring to FIGS. 10 and 15, a ferroelectric layer 400 having insulating characteristics may be formed on the insulating layer 300 (S500). According to one embodiment, the ferroelectric layer 400 may be formed by peeling off a CuInP₂S₆(CIPS) layer from a CuInP₂S₆(CIPS) bulk using a scotch tape, and dry transforming the peeled CuInP₂S₆(CIPS) layer on the insulating layer 300.

Referring to FIGS. 10 and 16, a gate electrode G may be formed on the ferroelectric layer 400 (S600). According to one embodiment, the gate electrode G may be formed by coating PMMA on the ferroelectric layer 400, etching a partial region thereof through electron beam lithography to expose the substrate 400, and depositing gold (Au) on the exposed ferroelectric layer 400 by using an electron beam evaporation method.

According to one embodiment, in the forming of the insulating layer 300 (S400) and the forming of the ferroelectric layer 400 (S500), thicknesses of the insulating layer 300 and the ferroelectric layer 400 are controlled, so that the capacitances of the insulating layer 300 and the ferroelectric layer 400 may be controlled to satisfy <Expression 1>, <Expression 2>, and <Expression 3> described above. Accordingly, steep-switching characteristics may be represented.

Hereinabove, the method for manufacturing a steep-switching memory device according to the embodiment of the present invention has been described. Hereinafter, various application examples of the steep-switching memory device according to an embodiment of the present invention will be described.

According to one embodiment, the steep-switching memory device may be applied to an autonomous vehicle system. More specifically, since the steep-switching memory device may form a strong output for a specific input value, it is possible to output an avoidance signal with respect to a target object to perform an avoidance function, and to implement a system that does not react to objects other than the target object. That is, it is possible to implement a low-power autonomous vehicle system that performs the avoidance function by outputting a strong signal for an approach of an object to be avoided and does not react to other signals.

Alternatively, according to another embodiment, the steep-switching memory device may be applied to a semiconductor inspection system. More specifically, since the steep-switching memory device may form a strong output with respect to a specific input value, it is possible to implement a system that reacts only to a specific residue within scanning electron microscopy (SEM) and transmission electron microscopy (TEM) analysis results. That is, in a surface analysis system of a modern semiconductor process that handles a large amount of input data, it is possible to implement a system that reacts only to a specific residue. Accordingly, it is possible to implement a low-power in-phase residue analysis system that operates only at a specific peak and provides improved throughput within a single time period.

Alternatively, according to still another embodiment, the steep-switching memory device may be applied to an electrocardiogram analysis system. More specifically, since the steep-switching memory device may form a strong output with respect to a specific input value, it is possible to implement a system that selectively generates an output value for a specific result among electrocardiogram analysis results. That is, since the selective output value may be generated for irregular electrocardiogram, it is possible to implement a system that performs a predictive symptom detection function of heart disease.

Alternatively, according to still another embodiment, the steep-switching memory device may be applied to an integrated computing system. More specifically, as a computing system in which an artificial intelligence computing layer is composed of the steep-switching memory device and a sensor layer is composed of a general ferroelectric device (or other devices having a sensing function), it is possible to implement a computing system capable of filtering only desired information even when the computing system is combined with any type of sensor device due to the steep-switching memory device having filtering performance.

Hereinabove, various application examples of the steep-switching memory device according to an embodiment of the present invention have been described. Hereinafter, a steep-switching memory device according to a modified example of the present invention will be described.

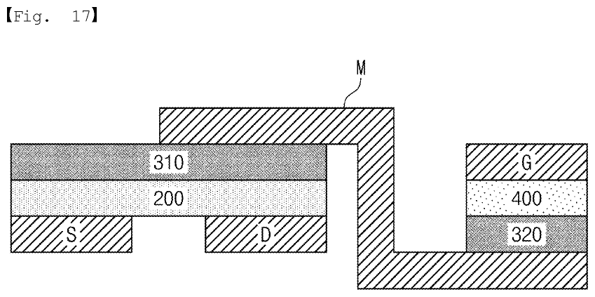

FIG. 17 is a view for explaining a steep-switching memory device according to a first modified example of the present invention.

Referring to FIG. 17, the steep-switching memory device according to the first modified example may include a source electrode S and a drain electrode D disposed to be spaced apart from each other, a ferroelectric channel layer 200 disposed on the source electrode S and the drain electrode D, a first insulating layer 310 disposed on the ferroelectric channel layer 200, a second insulating layer 320 disposed to be spaced apart from the first insulating layer 310, a connection layer M disposed between the first insulating layer 310 and the second insulating layer 320 such that one side of the connection layer M makes contact with the first insulating layer 310 and the other side of the connection layer M makes contact with the second insulating layer 320, a ferroelectric layer 400 disposed on the second insulating layer 320, and a gate electrode G disposed on the ferroelectric layer 400.

According to one embodiment, the source electrode S, the drain electrode D, the ferroelectric channel layer 200, the ferroelectric layer 400, and the gate electrode G may be the same as the source electrode S, the drain electrode D, the ferroelectric channel layer 200, the ferroelectric layer 400, and the gate electrode G of the steep-switching memory device according to the embodiment described with reference to FIG. 1. In addition, the first insulating layer 310 and the second insulating layer 320 according to the first modified example may be the same as the insulating layer 300 according to the embodiment.

The steep-switching memory device according to the first modified example may have an NC switch structure. More specifically, a left region (S/D/200/310/M) may perform a non-volatile memory characteristic expression function as a general ferroelectric FET, whereas a right region (M/320/400/G) may perform a steep-switching characteristic expression function as a steep-switching switch region. According to one embodiment, the steep-switching memory device according to the first modified example may represent steep-switching memory characteristics in which results of the left region and the right region are merged. In addition, a noised input signal may be input through the gate electrode G, and a filtered output signal may be output through the drain electrode D and the source electrode S.

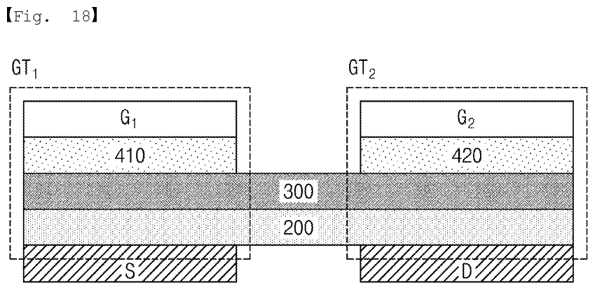

FIG. 18 is a view for explaining a steep-switching memory device according to a second modified example of the present invention.

Referring to FIG. 18, the steep-switching memory device according to the second modified example may include a first gate structure GT₁ and a second gate structure GT₂, in which the first gate structure GT₁ may include a source electrode S, a ferroelectric channel layer 200 disposed on the source electrode S, an insulating layer 300 disposed on the ferroelectric channel layer 200, a first ferroelectric layer 410 disposed on the insulating layer 300, and a first gate electrode G₁ disposed on the first ferroelectric layer 410, and the second gate structure GT₂ may include a drain electrode D, a ferroelectric channel layer 200 disposed on the drain electrode D, an insulating layer 300 disposed on the ferroelectric channel layer 200, a second ferroelectric layer 420 disposed on the insulating layer 300, and a second gate electrode G₂ disposed on the second ferroelectric layer 420, and the first gate structure GT₁ and the second gate structure GT₂ may include the drain electrode D, the ferroelectric channel layer 200 disposed on the drain electrode D The channel layer 200 and the insulating layer 300 may be shared.

According to one embodiment, the source electrode S, the drain electrode D, the ferroelectric channel layer 200, and the insulating layer 300, may be the same as the source electrode S, the drain electrode D, the ferroelectric channel layer 200, and the insulating layer 300 of the steep-switching memory device according to the embodiment described with reference to FIG. 1. Further, the first ferroelectric layer 410 and the second ferroelectric layer 420 according to the second modified example may be the same as the ferroelectric layer 400 according to the embodiment, and the first gate electrode G₁ and the second gate electrode G₂ according to the second modified example may be the same as the gate electrode G according to the embodiment.

The steep-switching memory device according to the second modified example may have a split gate structure, so that it is possible to secure memory characteristics and non-volatile characteristics due to the first ferroelectric layer 410 in the first gate structure GT₁, and to secure a negative capacitance effect and steep-switching characteristics in the second gate structure GT₂.

According to one embodiment, characteristics of a ferroelectric field effect transistor (FeFET) may be represented when a voltage is applied only to the first gate electrode G₁. In contrast, characteristics of a hysteresis-free negative capacitive transistor (NCFET) may be represented when a voltage is applied only to the second gate electrode G₂. In contrast, characteristics of the steep-switching memory device according to the embodiment may be represented when a voltage is applied to the first gate electrode G₁ and the second gate electrode G₂.

Hereinabove, the steep-switching memory devices according to the modified examples of the present invention have been described. Hereinafter, specific experimental examples for the steep-switching memory device and the reservoir computing system according to the embodiment of the present invention will be described.

### Experimental Example 1: Manufacture of Steep-Switching Memory Device

A PMMA resistive layer was spin-coated (450 K, 2000 rpm, 5 sec and 950 K, 4000 rpm, and 35 sec) on a p++ Si/SiO₂ substrate, and a partial region thereof was etched through electron beam lithography to expose the substrate, and gold (Au) having a thickness of about 20 nm was deposited in a high vacuum chamber (5×10⁻⁷) using an electron beam evaporator to form a source electrode and a drain electrode.

An α-In₂Se₃ layer, a h-BN layer, and a CuInP₂S₆ (CIPS) layer, which were peeled off from an α-In₂Se₃ bulk, a h-BN bulk, and a CuInP₂S₆ (CIPS) bulk, respectively, using a Scotch tape, were sequentially dry-stacked on the substrate on which the source electrode and the drain electrode were formed to form an α-In₂Se₃ ferroelectric channel layer, a h-BN insulating layer, and a CuInP₂S₆ (CIPS) ferroelectric layer.

Finally, the PMMA resistance layer was spin-coated (450 K, 2000 rpm, 5 sec and 950 K, 4000 rpm, and 35 sec) on the ferroelectric layer, and a partial region thereof was etched through electron beam lithography to expose the ferroelectric layer, and gold (Au) having a thickness of about 80 nm was deposited using an electron beam evaporator in a high vacuum chamber (5×10⁻⁷) to form a gate electrode, thereby manufacturing a steep-switching memory device according to the experimental example.

### Experimental Example 2: Confirmation of Electrical Characteristics of Steep-Switching Memory Device

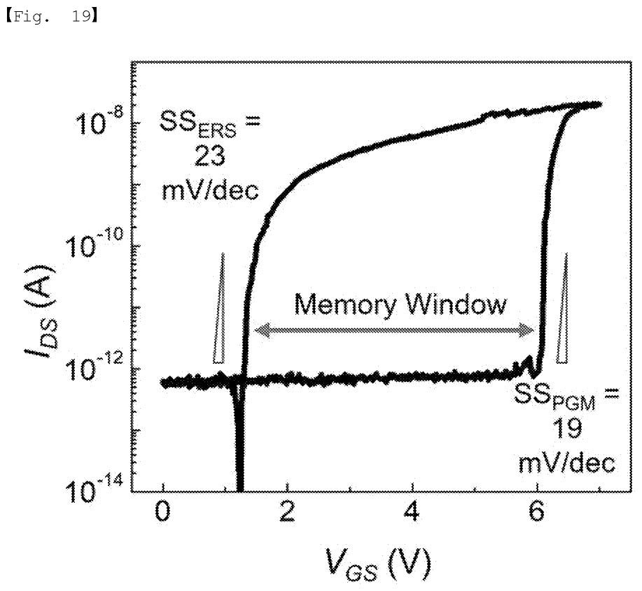

FIG. 19 is a view for explaining a drain current-gate voltage characteristics of a steep-switching memory device according to an experimental example of the present invention.

Referring to FIG. 19, a logarithmic scale drain current-gate voltage (I_{DS}-V_{GS}) curve measured in the steep-switching memory device according to the experimental example is shown.

As can be seen from FIG. 19, a transition to ON occurs under a voltage condition of 6 V in a program operation, and in this case, it can be seen that an SS value of 19 mV/dec is obtained. Alternatively, a transition to OFF occurs under a voltage condition of 1.7 V in an erase operation, and in this case, it can be seen that an SS value of 23 mV/dec is obtained. That is, it can be seen that hysteresis characteristics having a memory window of 4.3 V are represented.

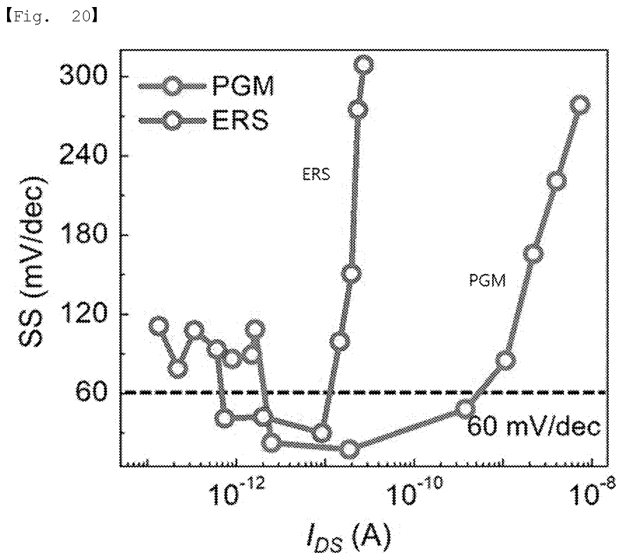

FIG. 20 is a view for explaining a change in a subthreshold swing voltage according to a drain current of the steep-switching memory device according to the experimental example of the present invention.

Referring to FIG. 20, results of a drain current-subthreshold swing value (I_{DS}-SS) during the program operation and the erase operation, which are obtained in FIG. 19, are shown.

As can be seen from FIG. 20, it can be seen that switching characteristics of a minimum of 19 mV/dec and an average of 34 mV/dec are represented in the program operation. In contrast, it can be seen that switching characteristics of a minimum of 23 mV/dec and an average of 32 mV/dec are represented in the erase operation.

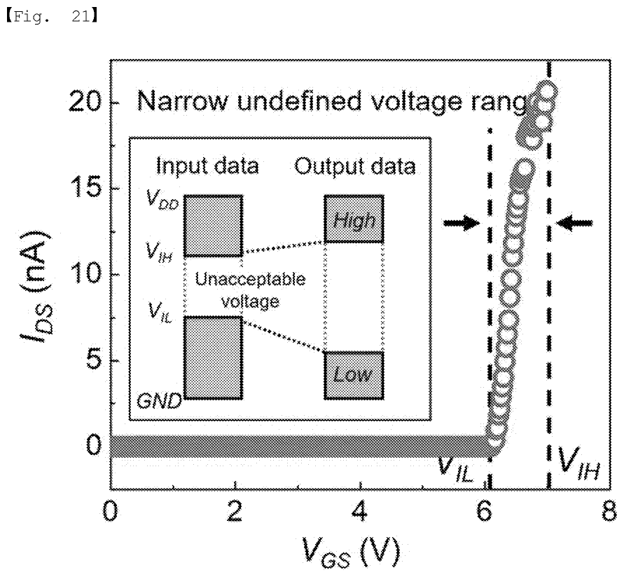

FIG. 21 is a view for explaining drain current-gate voltage characteristics (linear scale) of the steep-switching memory device according to the experimental example of the present invention and an undefined output range between V_{IL} and V_{IH} obtained therefrom.

Referring to FIG. 21, results of a linear scale drain current-gate voltage (I_{DS}-V_{GS}) are shown. As can be seen from FIG. 21, it can be seen that a differential value between a maximum value V_{IL} of a voltage, which is applied to the gate electrode to have a Low state (a state where polarization directions of the ferroelectric channel layer and the ferroelectric layer are aligned in opposite directions) and a minimum value V_{IH} of a voltage, which is applied to the gate electrode to have a High state (a state where the polarization directions of the ferroelectric channel layer and the ferroelectric layer are aligned in the same direction), is less than 1 V. That is, it can be seen that a generation range of an undefined (unpredicted) output value that is not defined as the Low state and the High state may be minimized, and a current that is less than the voltage V_{IL} applied to the gate electrode G to have the Low state may be filtered close to 0. In other words, it is described that noise filtering may be performed by minimizing a low signal output of input data and a generation probability of the undefined output value due to steep-switching characteristics of the steep-switching memory device according to the experimental example.

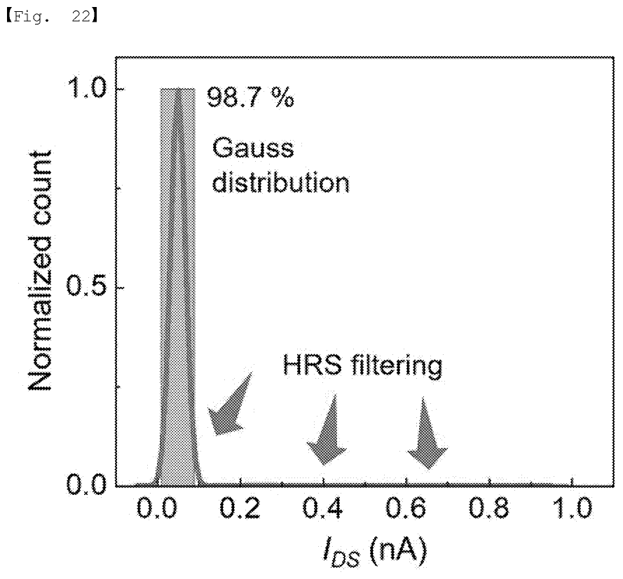

FIG. 22 is a view for explaining a drain current distribution histogram of the steep-switching memory device according to the experimental example of the present invention.

Referring to FIG. 22, a distribution histogram of a drain current, which is output at a voltage less than the maximum value V_{IL} of the voltage applied to the gate electrode to have the Low state (the state where the polarization directions of the ferroelectric channel layer and the ferroelectric layer are aligned in opposite directions), is shown.

As can be seen from FIG. 22, it can be seen that an intensity of the output drain current is less than 0.2 nA, and a current value close to 0 is generated with a frequency of 98.7%. Accordingly, it is further described that strict data filtering may be performed.

### Experimental Example 2: Verification of Event-Based Reservoir Characteristics of Steep-Switching Memory Device

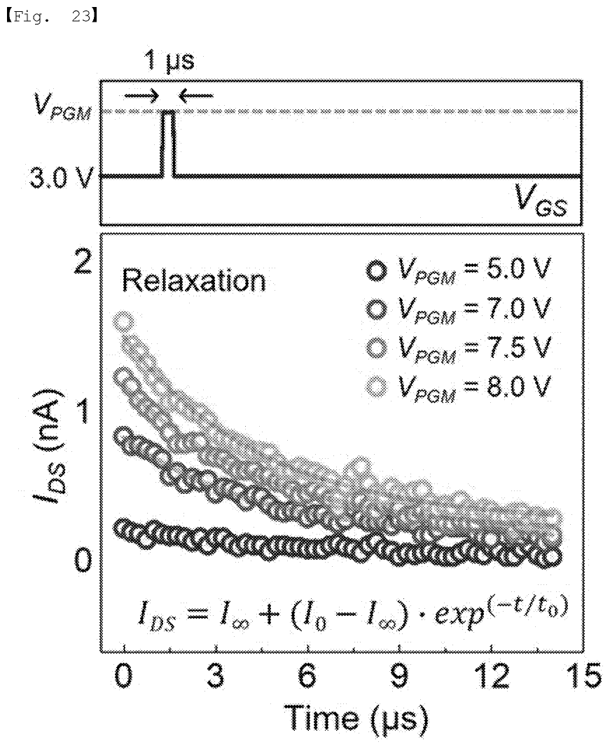

FIG. 23 is a view for explaining drain current-time (I_{DS}-time) results of short-term memory characteristics according to a pulse voltage applied to a gate electrode of the steep-switching memory device according to the experimental example of the present invention.

Referring to FIG. 23, results of measurement under conditions of program operation input voltage V_{PGM}=5 to 8 V, read operation input voltage V_{read}=3 V, and pulse interval=1 μs are shown.

As shown in FIG. 23, as the input voltage disappears regardless of a magnitude of the input voltage applied to the gate electrode, it can be seen that the input voltage is gradually restored to an initial state I₀ for a predetermined time. This means short-term memory characteristics, and a reservoir device requires non-linear conversion characteristics that reflect recently generated signals using the short-term memory characteristics and output results thereof.

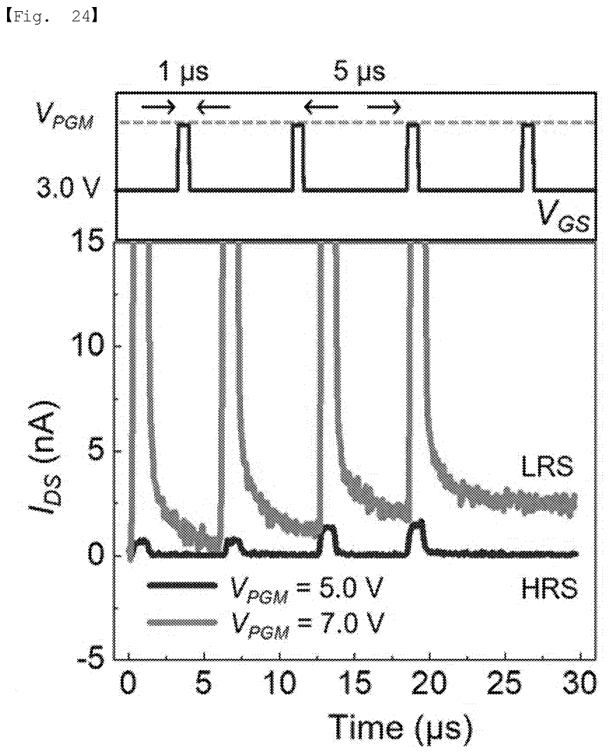

FIG. 24 is a view for explaining drain current-time characteristics according to a pulse voltage applied to the gate electrode of the steep-switching memory device according to the experimental example of the present invention.

Referring to FIG. 24, drain voltage current-time (I_{DS}-time) results with respect to the pulse voltage repeatedly applied four times are shown. More specifically, results of measurement under conditions of a program operation input voltage V_{PGM} of a low resistance state (LRS)=7 V, a program operation input voltage V_{PGM} of a high resistance state (HRS)=5 V, a read operation input voltage V_{read}=3 V, a pulse interval=1 μs, and an inter-pulse interval=5 μs, are shown.

As can be seen from FIG. 24, in a low resistance state (LRS) where the intensity of the applied voltage is 7 V, the drain current intensity in the read operation tends to gradually increase after the voltage is applied. However, in a high resistance state (HRS) where the intensity of the applied voltage is 5 V, it can be seen that the pulse application result is not reflected during a read operation. That is, it can be seen that the steep-switching memory device according to the experimental example selectively performs a memory operation only for an applied voltage higher than V_{IH}. V_{IH} means a minimum value of the voltage applied to the gate electrode such that the polarization directions of the ferroelectric channel layer and the ferroelectric layer are aligned in the same direction. In addition, when the input signal is repeatedly applied in the low resistance state, the output signal value gradually increases as the number of repetitions increases, so that short-term memory characteristics of memorizing a recent input history for a short time may be confirmed once again.

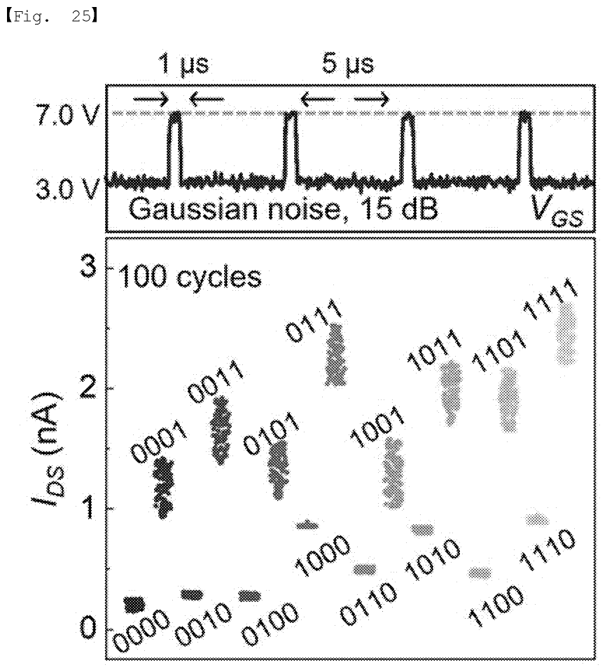

FIG. 25 is a view for explaining drain current-time characteristics according to a repeated pulse voltage (addition of Gaussian noise) applied to the gate electrode of the steep-switching memory device according to the experimental example of the present invention.

Referring to FIG. 25, drain current results generated under a pulse condition to which noise is added are shown. More specifically, results of measurement under conditions of a program operation input voltage V_{PGM}=7 V, a read operation input voltage V_{read}=3 V, a pulse interval=1 μs, an inter-pulse interval=5 μs, and 100 repetitions, are shown.

As can be seen from FIG. 25, it can be seen that all of the 16 cases up to 0000-1111 are stably classified, and results, in which 0 is input at the end, generate a small distribution result. That is, it can be seen that a memory operation is selectively performed only for an applied voltage higher than V_{IH} even when the noise is added.

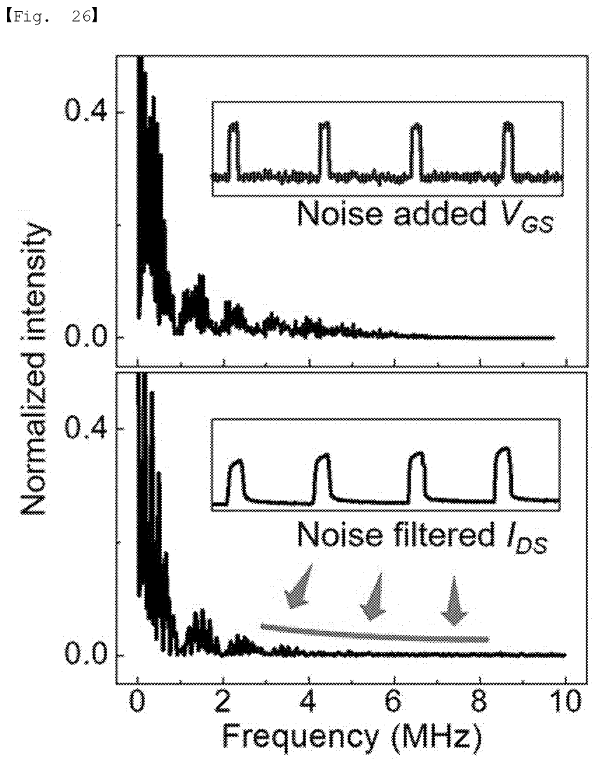

FIG. 26 is a view for explaining Fourier transform results of the repeated pulse voltage (addition of Gaussian noise) applied to the gate electrode of the steep-switching memory device according to the experimental example of the present invention.

Referring to FIG. 26, results of Fourier transforming the noise-added input pulse voltage and the drain current results generated in the steep-switching memory device, are shown.

As can be seen from FIG. 26, it can be seen that a signal in a high-frequency region is reduced in the lower part of FIG. 26 compared to the upper part of FIG. 26. That is, it can be seen that the device itself reduces the intensity of the high-frequency region corresponding to a Gaussian noise region. This is a result that may be directly confirmed that the device itself has performed filtering on the noise signal that is rapidly repeated.

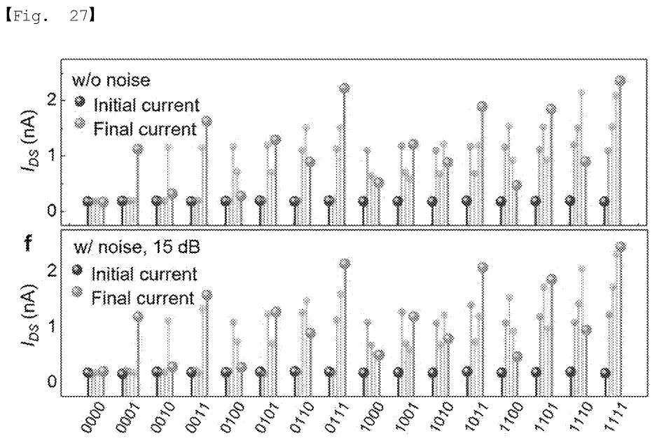

FIG. 27 is a view for explaining non-linear transformation output results of the steep-switching memory device according to the experimental example of the present invention, depending on the presence or absence of noise.

Referring to FIG. 27, drain current results for a pulse voltage (16 cases up to 0000-1111) applied to the steep-switching memory device according to the experimental example are shown according to the presence or absence of noise. w/o means a case where there is no noise, and w/o means a case where there is noise.

As can be seen from FIG. 27, it can be seen that the order of intensities of the respective signals is constantly maintained in the steep-switching memory device according to the experimental example regardless of the presence or absence of noise. This is a result of simultaneously reflecting filtering characteristics and memory characteristics of the device, and it can be seen that the performance of the event-based reservoir that performs filtering and non-linear transformation with only a single device is obtained.

### Experimental Example 3: Implementation of Event-Based Reservoir Computing System Using Steep-Switching Memory Device

### (Noise MNIST Classification Evaluation)

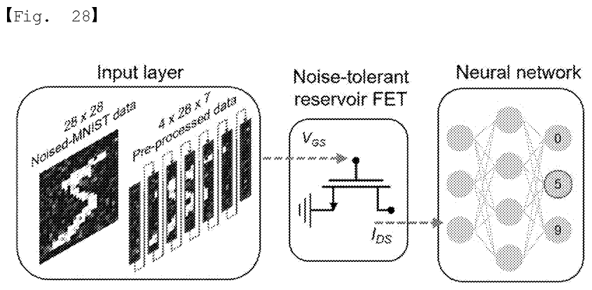

FIG. 28 is a schematic view of the entire process of MNIST classification with noise applied.

Referring to FIG. 28, a method for learning/evaluating MNIST data in which noise is applied is shown. In order to simplify the experiment, the experiment was performed by dividing the MNIST data of the initial 28*28 pixels by 4*7*28 and inputting device current data corresponding to 4 bits. Noise MNIST classification evaluation was performed by learning/evaluating the generated current results using a neural network system.

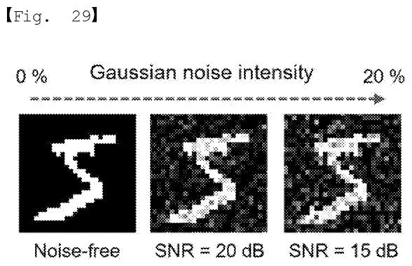

FIG. 29 is a view for explaining results of change in MNIST data according to an increase of Gaussian noise intensity.

Referring to FIG. 29, MNIST data transformed according to noise intensity may be visually confirmed.

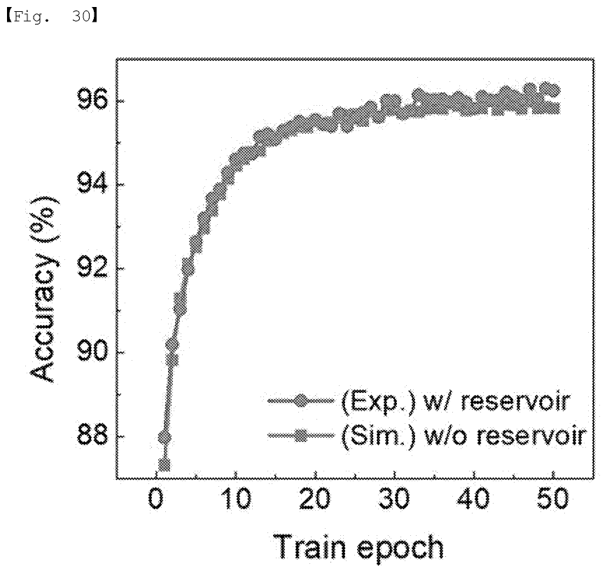

FIG. 30 is a view for explaining a relationship between learning accuracy and the number of repetitions of the reservoir computing system based on an event performed using noise-free MNIST data.

Referring to FIG. 30, results of learning performed using noise-free data are shown. The learning performed as a result output from the device was expressed in purple (w/reservoir), and the learning performed as a virtual result was expressed in gray (w/o reservoir). As can be seen from FIG. 30, it can be seen that the reservoir computing system based on the steep-switching memory device according to the experimental example represents stable performance in terms of learning.

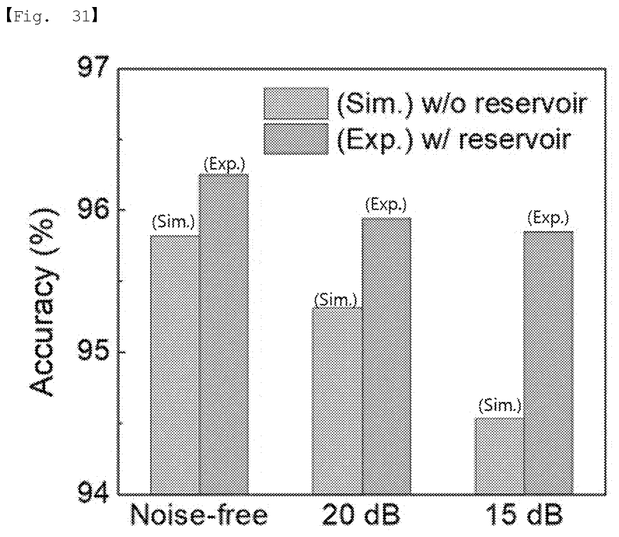

FIG. 31 is a view for explaining recognition rate evaluation results of the reservoir computing system based on an event performed using MNIST data for each noise intensity.

Referring to FIG. 31, evaluation results obtained using various MNIST data for each noise intensity are shown. The results are evaluated based on data in which noise is added to the learning result performed using the noise-free data, and it can be seen that the results obtained through the steep-switching memory device show that a reduction in a recognition rate is minimized. In addition, it can be seen that noise tolerance stability is secured even when the noise intensity increases.

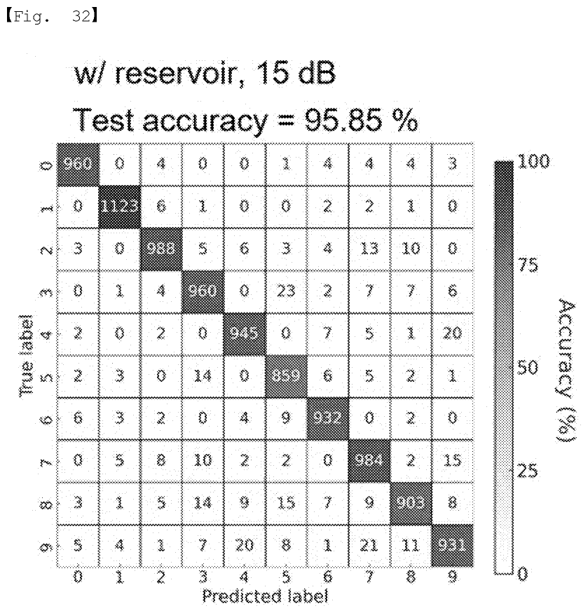

FIG. 32 is a view for explaining confusion matrix results of MNIST classification evaluated under a 15 dB condition.

Referring to FIG. 32, a confusion matrix showing an actual classification result of MNIST in a 15 dB noise environment is shown. As can be seen from FIG. 32, a recognition rate of 95.85% is shown, which proves that the steep-switching memory device filters noise by itself to output a result close to an ideal MNIST and leads to an increase in the recognition rate of the system.

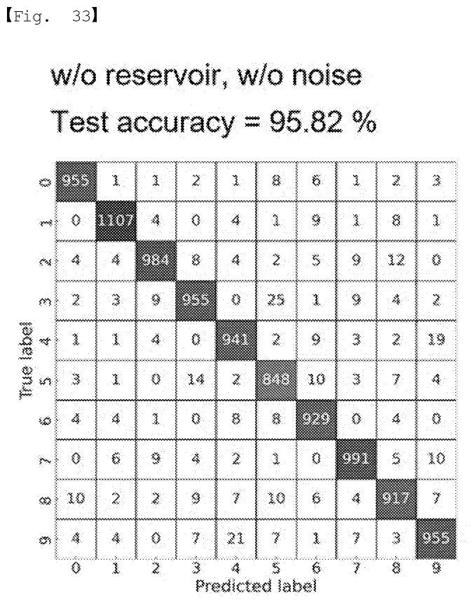

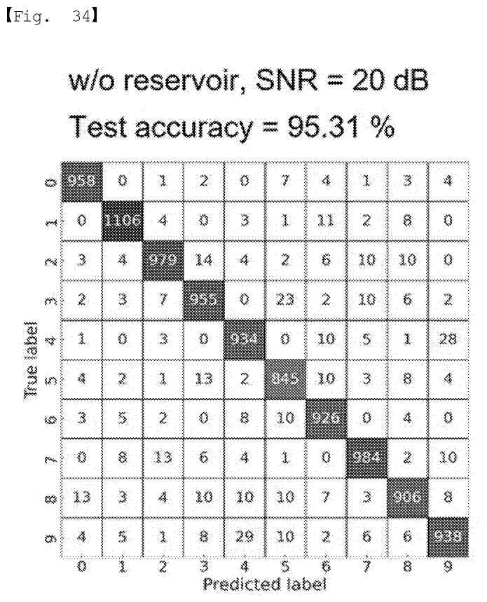

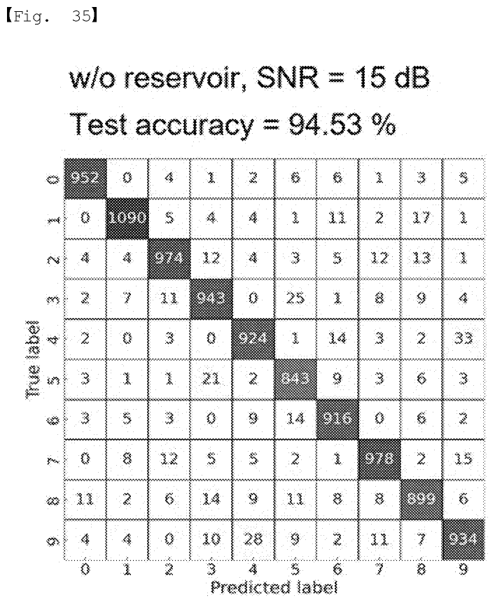

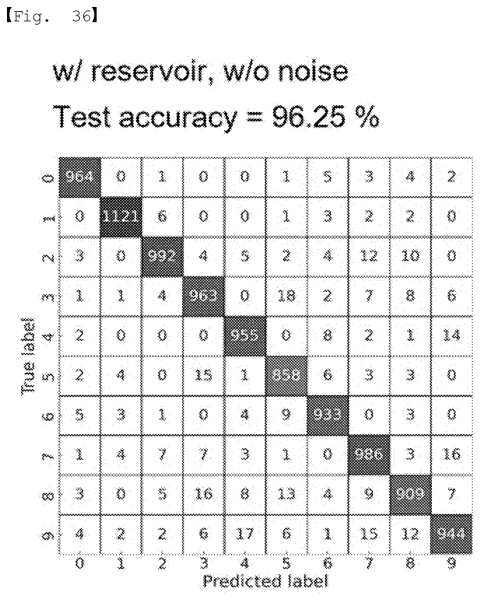

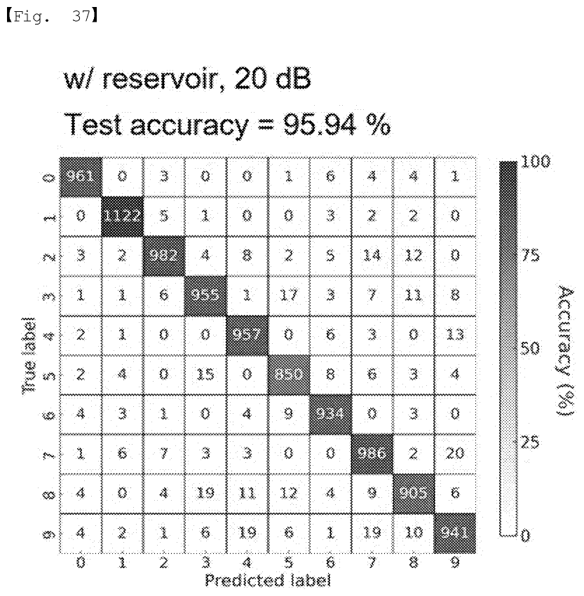

FIG. 33 is a view for explaining confusion matrix results of evaluation performed under w/o reservoir (virtual data) and w/o noise conditions, FIG. 34 is a view for explaining confusion matrix results of evaluation performed under w/o reservoir (virtual data) and 20 dB noise conditions, FIG. 35 is a view for explaining confusion matrix results of evaluation performed under w/o reservoir (virtual data) and 15 dB noise conditions, FIG. 36 is a view for explaining confusion matrix results of evaluation performed under w/reservoir (data output from the device) and w/o noise conditions, and FIG. 37 is a view for explaining confusion matrix results of evaluation performed under w/reservoir (data output from the device) and w/o noise conditions.

Referring to FIGS. 33 to 37, confusion matrix results showing actual evaluation results of FIG. 31 are shown. FIG. 33 shows results of evaluation of a recognition rate of 95.82%, which is performed using a virtual output value based on noise-free MNIST data, FIG. 34 shows results of evaluation of a recognition rate of 95.31%, which is performed using a virtual output value based on MNIST data in which 20 dB noise is added, FIG. 35 shows results of evaluation of a recognition rate of 94.53%, which is performed using a virtual output value based on MNIST data (15 dB), FIG. 36 shows results of evaluation of a recognition rate of 96.25%, which is performed using an output value of the steep-switching memory device based on the noise-free MNIST data, and FIG. 37 shows results of evaluation of a recognition rate of 95.94%, which is performed using an output value of the steep-switching memory device based on MNIST data (20 dB).

While the present invention has been described in connection with the embodiments, it is not to be limited thereto but will be defined by the appended claims. In addition, it is to be understood that those skilled in the art may substitute, change, or modify the embodiments in various forms without departing from the scope and spirit of the present invention.

What is claimed is:

1. A steep-switching memory device comprising:
a source electrode and a drain electrode disposed on a substrate to be spaced apart from each other;
a ferroelectric channel layer disposed on the substrate to cover the source electrode and the drain electrode;
an insulating layer disposed on the ferroelectric channel layer;
a ferroelectric layer disposed on the insulating layer and having insulating characteristics; and
a gate electrode disposed on the ferroelectric layer,
wherein capacitances of the insulating layer and the ferroelectric layer are controlled, so that an internal voltage, which is formed at a boundary surface between the ferroelectric layer and the insulating layer, is amplified to be higher than a voltage applied to the gate electrode, and steep-switching characteristics having a subthreshold swing (SS) value of less than 60 mV/dec are represented.

2. The steep-switching memory device of claim 1, wherein the capacitances of the insulating layer and the ferroelectric layer are controlled to satisfy the following <Expression 1>, <Expression 2>, and <Expression 3>.
$${C}_{FE} < 0 \qquad < Expression 1 >$$
$$( {C}_{F E} : Capacitance of the ferroelectric layer )$$
$$\vert {C}_{FE} \vert > {C}_{DE} \qquad < Expression 2 >$$
$$( \vert {C}_{FE} \vert : Absolute value of capacitance of the ferroelectric layer , {C}_{DE} : Capacitace of the insulating layer )$$
$${C}_{ST} > 0 \qquad < Expression 3 >$$
$$( {C}_{ST} : Total capacitance of a stack structure in which the ferroelectric layer is stacked on the insulating layer ) .$$

3. The steep-switching memory device of claim 1, wherein the insulating layer and the ferroelectric layer are electrically connected in series.

4. The steep-switching memory device of claim 1, wherein, when a voltage equal to or higher than a reference voltage is applied to the gate electrode, dipole coupling is formed between the ferroelectric layer and the ferroelectric channel layer such that a polarization direction of the ferroelectric layer is the same as a polarization direction of the ferroelectric channel layer.

5. The steep-switching memory device of claim 4, wherein hysteresis characteristics having a memory window of 4.3 V is represented due to the dipole coupling between the ferroelectric layer and the ferroelectric channel layer.

6. The steep-switching memory device of claim 1, wherein the steep-switching memory device has a subthreshold swing value of less than 20 mV/dec.

7. The steep-switching memory device of claim 1, wherein the ferroelectric channel layer includes any one of alpha-indium selenide (α-In₂Se₃), MoSSe, MoTe, SnS, SnSe, SnTe, GeS, GeSe, and GeTe.

8. The steep-switching memory device of claim 1, wherein the insulating layer includes aluminum oxide (Al₂O₃), silicon oxide (SiO₂), hafnium oxide (HfO₂), and hexagonal boron nitride (h-BN).

9. The steep-switching memory device of claim 1, wherein the ferroelectric layer includes any one of hafnium zirconium oxide (HZO), CuCrP₂S₆, CuCrP₂Se₆, CuVP₂S₆, CuVP₂Se₆, CuInP₂Se₆, CuInP₂S₆ (CIPS), AgBiP₂Se₆, Sc₂CO₂, GaTeCl, and g-C₆N₈H.

10. The steep-switching memory device of claim 1, wherein, the capacitances of the insulating layer and the ferroelectric layer are controlled as thicknesses of the insulating layer and the ferroelectric layer are controlled.

11. A method for manufacturing a steep-switching memory device, the method comprising:
preparing a substrate;
forming a source electrode and a drain electrode on the substrate to be spaced apart from each other;
forming a ferroelectric channel layer on the substrate to cover the source electrode and the drain electrode;
forming an insulating layer on the ferroelectric channel layer;
forming a ferroelectric layer having insulating characteristics on the insulating layer; and
forming a gate electrode on the ferroelectric layer,
wherein, in the forming of the insulating layer and the forming of the ferroelectric layer, capacitances of the insulating layer and the ferroelectric layer are controlled, so that an internal voltage, which is formed at a boundary surface between the ferroelectric layer and the insulating layer, is amplified to be higher than a voltage applied to the gate electrode, and steep-switching characteristics having a subthreshold swing (SS) value of less than 60 mV/dec are represented.

12. The method of claim 11, wherein the capacitances of the insulating layer and the ferroelectric layer are controlled to satisfy the following <Expression 1>, <Expression 2>, and <Expression 3>.
$${C}_{FE} < 0 \qquad < Expression 1 >$$
$$( {C}_{F E} : Capacitance of the ferroelectric layer )$$
$$\vert {C}_{FE} \vert > {C}_{DE} \qquad < Expression 2 >$$
$$( \vert {C}_{FE} \vert : Absolute value of capacitance of the ferroelectric layer , {C}_{DE} : Capacitace of the insulating layer )$$
$${C}_{ST} > 0 \qquad < Expression 3 >$$
$$( {C}_{ST} : Total capacitance of a stack structure in which the ferroelectric layer is stacked on the insulating layer ) .$$

13. A reservoir computing system comprising a source electrode and a drain electrode disposed on a substrate to be spaced apart from each other, a ferroelectric channel layer disposed on the substrate to cover the source electrode and the drain electrode, an insulating layer disposed on the ferroelectric channel layer, a ferroelectric layer disposed on the insulating layer and having insulating characteristics, and a gate electrode disposed on the ferroelectric layer,
wherein noise in an input signal is filtered using steep-switching characteristics generated by controlling capacitances of the insulating layer and the ferroelectric layer,
short-term memory characteristics are implemented using dipole coupling formed between the ferroelectric channel layer and the ferroelectric layer,
non-linear transform characteristics, in which the input signal is non-linearly transformed, are implemented by the steep-switching characteristics and the short-term memory characteristics, and
the steep-switching characteristics are defined such that an internal voltage formed at a boundary surface between the ferroelectric layer and the insulating layer is amplified to be higher than a voltage applied to the gate electrode, and a subthreshold swing (SS) value is less than 60 mV/dec.

14. The reservoir computing system of claim 13, wherein a differential value between a maximum value of a voltage, which is applied to the gate electrode so as to have a state where polarization directions of the ferroelectric channel layer and the ferroelectric layer are aligned in opposite directions, and a minimum value of a voltage, which is applied to the gate electrode so as to have a state where the polarization directions of the ferroelectric channel layer and the ferroelectric layer are aligned in the same direction, is less than 1 V.

15. The reservoir computing system of claim 13, wherein, when the input signal is removed after the input signal is applied such that the dipole coupling is formed between the ferroelectric channel layer and the ferroelectric layer, an output signal value output from the input signal is gradually reduced for a predetermined time.

16. The reservoir computing system of claim 14, wherein, when the input signal is repeatedly applied, the output signal value gradually increases as the number of repetitions increases.

17. The reservoir computing system of claim 13, wherein the noise in the input signal is filtered without additional noise filtering circuits and devices.

18. The reservoir computing system of claim 13, wherein the input signal is applied through the gate electrode, and an output signal is output through the drain electrode.

19. The reservoir computing system of claim 13, wherein a program operation is performed as a first voltage higher than a reference voltage is applied,
an erase operation is performed as a second voltage lower than the reference voltage is applied, and
a read operation is performed as a third voltage between the reference voltage and the second voltage is applied.
